(19) United States
(12) Patent Application Publication
(10) Pub. No.: US 2012/0139028 A1
(43) Pub. Date: Jun. 7, 2012

(54) SEMICONDUCTOR MEMORY DEVICE AND EMTHOD OF FORMING THE SAME

(75) Inventors: Jongchul Park, Hwaseong-si (KR); Inseak Hwang, Suwon-si (KR); Sangsup Jeong, Suwon-si (KR)

(73) Assignee: SAMSUNG ELECTRONICS CO., LTD., Suwon-si (KR)

(21) Appl. No.: 13/302,676

(22) Filed: Nov. 22, 2011

(30) Foreign Application Priority Data
Dec. 1, 2010 (KR) 10-2010-0121582

(51) Int. Cl. H01L 29/792; H01L 27/092

(52) U.S. Cl. 257/324; 257/334; 257/E29.309; 257/E27.062

(57) ABSTRACT

A semiconductor memory device includes a device isolation pattern defining an active region of a substrate, a buried gate electrode extending longitudinally in a given direction across the active region, a first impurity region and a second impurity region disposed along respective sides of the buried gate electrode, a conductive pad disposed on the substrate and electrically connected to the first impurity region, a first contact plug disposed on the substrate and electrically connected to the second impurity doping region, and a second contact plug disposed on the pad.

### PRIORITY STATEMENT

This U.S. non-provisional patent application claims priority under 35 U.S.C. §119 of Korean Patent Application No. 10-2010-0121582, filed on Dec. 1, 2010, the entire contents of which are hereby incorporated by reference.

### BACKGROUND

The inventive concept relates to semiconductor memory devices and methods of forming the same. More particularly, the inventive concept relates to a semiconductor memory device including a buried gate electrode and to a method of forming the same.

There are growing demands in the electronics industry for portable devices, such as cell phones and notebooks, having increased lightweight, miniaturized, high speed, multi-function, high performance and low cost characteristics. In general, the degree to which semiconductor devices can be integrated and the process margin of semiconductor devices must be increased to meet one or more of those demands.

One area, in particular, which is under consideration for increasing the process margin of and degree to which semiconductor devices can be integrated, is the configuration of word lines of semiconductor devices and their electrical interconnections.

### SUMMARY

According to one aspect of the inventive concept, there is provided a semiconductor memory device comprising: a substrate having first and second regions of impurities of different conductivity types, a device isolation defining an active region that includes the first and second impurity regions, a buried gate electrode extending longitudinally in one direction along the active region, a conductive pad disposed on the substrate and electrically connected to the first impurity region, a first contact plug disposed on the substrate and electrically connected to the second impurity region, and second contact plug disposed on and electrically connected to the pad, and wherein the first and second impurity regions are disposed along opposite sides of the buried gate electrode, respectively.

According to one aspect of the inventive concept, there is provided a semiconductor memory device comprising: a substrate, a device isolation pattern disposed in the substrate and dividing the substrate into active regions, buried gate electrodes extending in the substrate parallel to each other longitudinally in a first direction across the active regions and the device isolation pattern therebetween, conductive pads disposed on the substrate and electrically connected to the first impurity regions, respectively, first contact plugs disposed on the substrate and electrically connected to the second impurity regions, respectively, and second contact plugs disposed on and electrically connected to the pads, respectively, and wherein each active region has first regions of impurities of one conductivity type and a second region of impurities of the other conductivity type, the second impurity region is located between the first impurity regions, a pair of the buried gate electrodes crosses each active region and is interposed between the first impurity regions of the active region, and the second impurity region of each active region is interposed between the pair of buried gate electrodes that crosses the active region.

According to still another aspect of the inventive concept, there is provided a method of forming a semiconductor memory device comprising: forming a device isolation pattern in a substrate to define an active region, forming a buried gate electrode by forming a groove in the substrate extending longitudinally in a first direction across the active region and the device isolation pattern, and forming an electrode in the groove, doping the active region of the substrate with impurities of different conductivity types to form a first impurity region and a second impurity region, forming a conductive pattern that extends longitudinally parallel to the buried gate electrode and which is electrically connected to the first impurity region, and patterning the conductive pattern to form a conductive pad connected to the first impurity region, and wherein the forming of the buried gate electrode and the doping of the active region are carried out such that the first and second impurity regions are disposed adjacent opposite sides of the buried gate electrode, respectively.

### BRIEF DESCRIPTION OF THE FIGURES

These and other features, aspects and advantages of the inventive concept will be more apparent from the detailed descriptions of embodiments thereof that follows, as made with reference to the accompanying drawings. In the drawings:

FIG. 1A is a plan view of a semiconductor memory device in accordance with the inventive concept;

FIG. 1B is a sectional view taken along line I-I′ of FIG. 1A;

FIG. 1C is a sectional view taken along line II-II′ of FIG. 1A;

FIG. 1D is an enlarged view of ‘A’ part of FIG. 1C for explaining an example of an information storage element of FIG. 1C.

FIG. 1E is an enlarged of another example of an information storage element of the semiconductor device according to the inventive concept, corresponding to part ‘A’ in FIG. 1C;

FIGS. 2A, 3A, . . . 18A are plan views, FIGS. 2B, 3B . . . 18B are sectional views taken along lines I-I′ of FIGS. 2A 3A, . . . 18A, respectively, and FIGS. 2C, 3C, . . . 18C are sectional views taken along lines II-II′ of FIGS. 2A 3A, . . . 18A, respectively, illustrating a method of fabricating a semiconductor memory device in accordance with the inventive concept;

FIG. 19 is a block diagram of an example of a memory system including a semiconductor device in accordance with the inventive concept; and

FIG. 20 is a block diagram of an example of a memory card including a semiconductor device in accordance with the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Furthermore, spatially relative terms, such as “top” and “bottom” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use. In addition, the terms “top” and “bottom” as used to describe a surface generally refer not only to the orientation depicted in the drawings but to the fact that the surface is the uppermost or bottommost surface in the orientation depicted, as would be clear from the drawings and context of the written description.

Furthermore, as used herein, the term “and/or” includes any and all practical combinations of one or more of the associated listed items.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. Also, the term “pattern” generally refers to a feature or layer that results from a patterning process and thus, as the context and drawings will make clear, may refer to an individual feature that is repeated in a particular layer or a layer itself that has been etched.

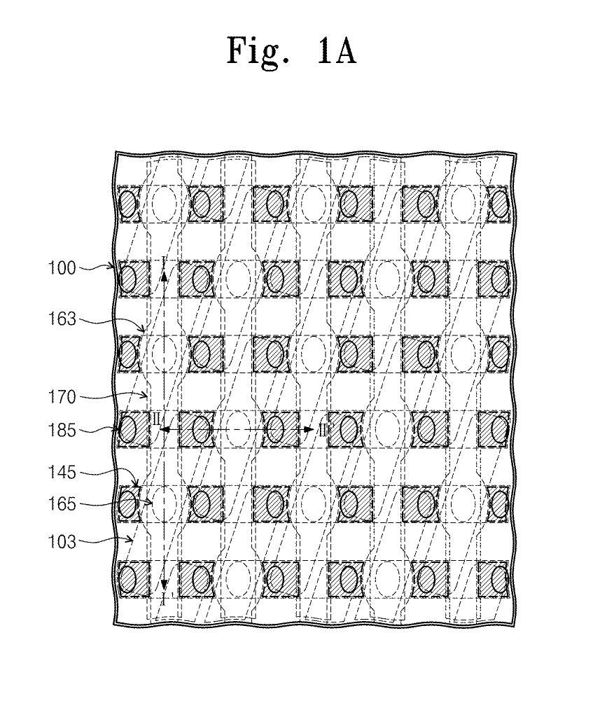

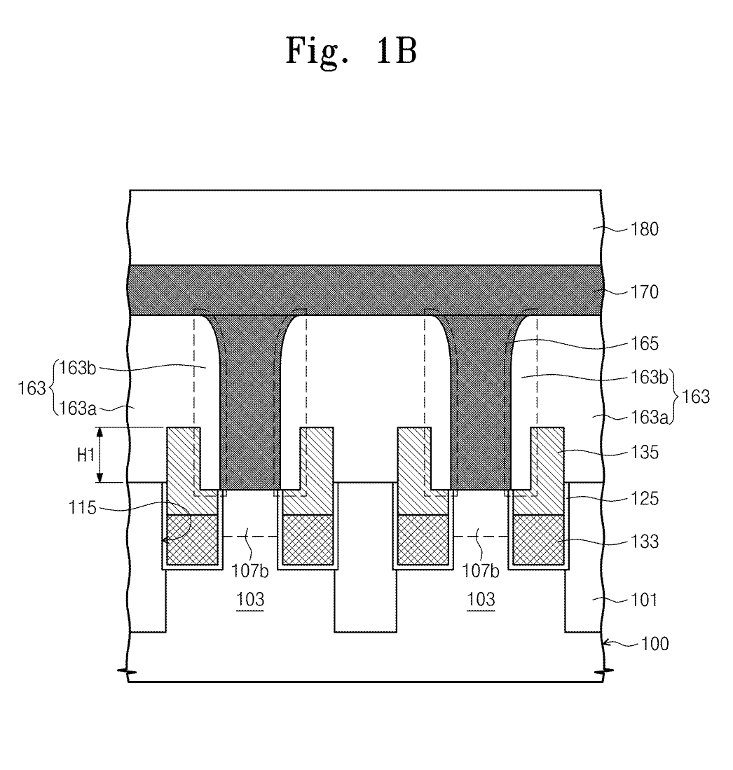

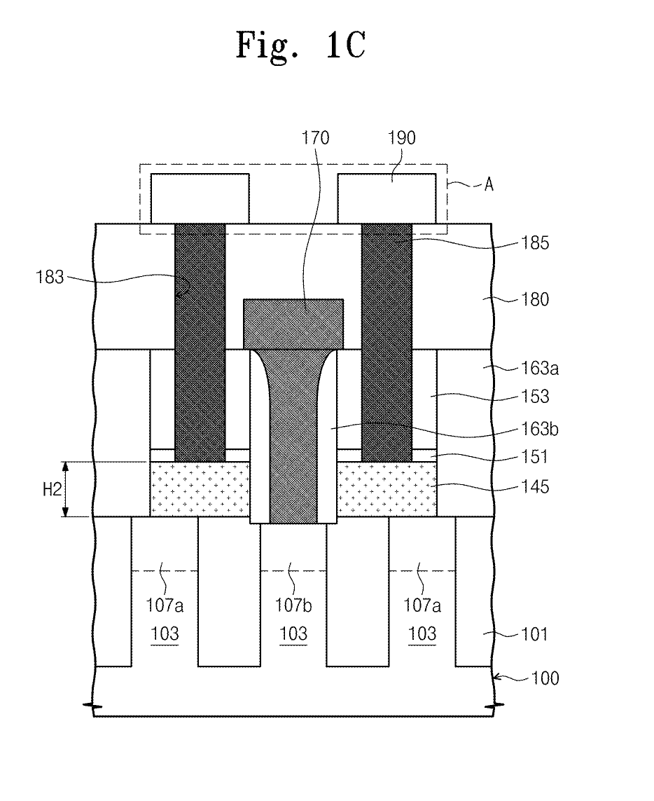

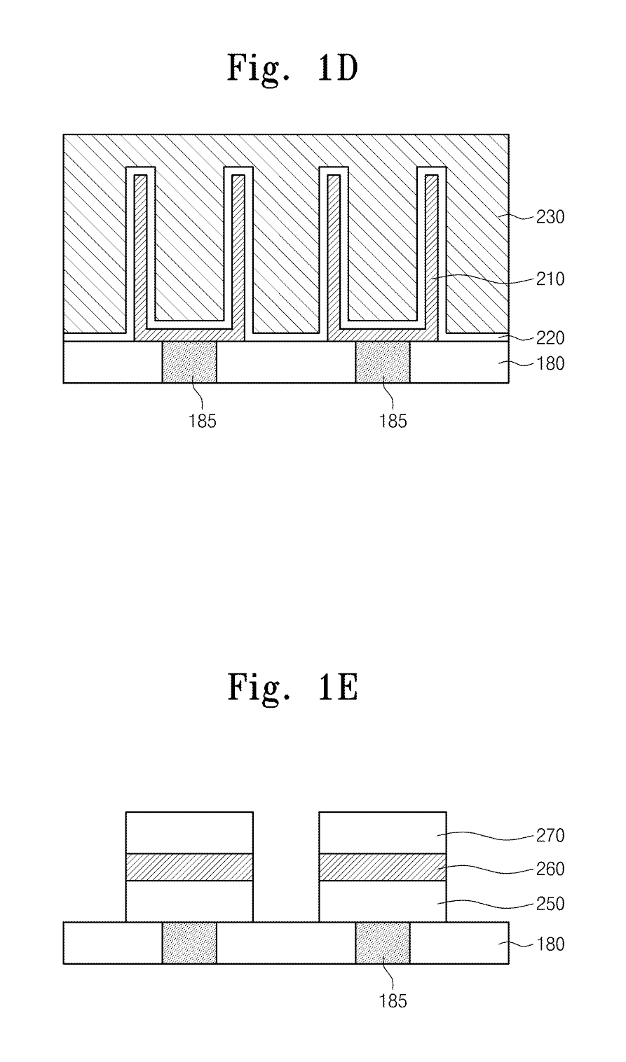

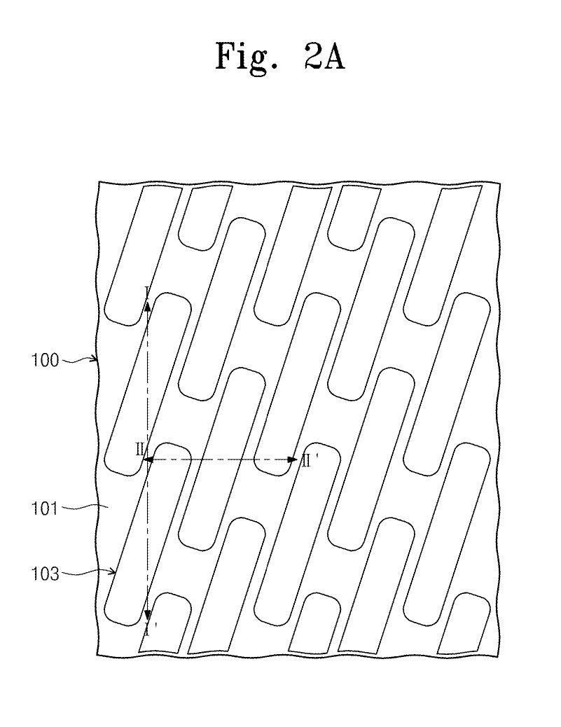

A semiconductor memory device in accordance with the inventive concept will now be described with reference to FIGS. 1A-1C.

The semiconductor memory device comprises a substrate 100, and a device isolation pattern 101 defining at least one active region 103 in the substrate 100. In the illustrated example, the device isolation pattern 101 is a shallow trench isolation (STI) structure. To this end, the device isolation pattern 101 comprises insulating material. For example, the device isolation pattern 101 may be of at least one material selected from the group consisting of silicon oxide, silicon nitride and silicon oxynitride. The substrate 100 comprises semiconductor material. For example, the substrate 100 may be a substrate of at least one of silicon and germanium.

In this embodiment, the device isolation pattern 101 divides the substrate 100 into a two-dimensional array of active regions 103, i.e., rows in which the active regions 103 of each row are spaced from each other in a first direction and columns in which active regions 103 of each column are spaced from each other in a second direction crossing the first direction. Furthermore, the active regions in each row are staggered with respect to (e.g., are disposed halfway between) the active regions of each row adjacent thereto. Likewise, the active regions in each column are staggered (e.g., are disposed halfway between) with respect to the active regions in each column adjacent thereto. Also, each of the active portions 103 may be elongated in a third direction which lies in the same plane as but is oblique with respect to the first and second directions.

Grooves 115 are also defined in the substrate 100. When viewed in plan, each groove 115 extends linearly in the first direction across several of the active regions 103 and the device isolation pattern 101 therebetween.

A buried gate electrode 133 is disposed in each groove 115. Thus, the buried gate electrode 133 extends linearly in the first direction across several active regions 103 and the device isolation pattern 101 therebetween. The top surface of the buried gate electrode 133 may be disposed beneath the level of the top surface of the substrate 100. Furthermore, the buried gate electrodes 133 may be of at least one conductive material selected from the group consisting of doped semiconductors, conductive metal nitrides (e.g., titanium nitride, tantalum nitride or tungsten nitride) and metals (e.g., ruthenium, iridium, titanium, tungsten or tantalum).

In another example (not shown), each buried gate electrode 133 comprises a bulk pattern disposed in the groove 115 and a liner pattern interposed between the bulk pattern and the surfaces delimiting the groove 115. In this case, the liner pattern performs a barrier function for the bulk pattern. Also, the liner pattern may be used as a control for the effective work function of a gate electrode. Also, the bulk pattern and the liner pattern are preferably of materials having an etching selectivity with respect to each other. For example, the liner pattern may be of titanium nitride and the bulk pattern may be of tungsten.

Returning now to the illustrated example, a gate dielectric pattern 125 is interposed between the buried gate electrode 133 and the surfaces delimiting the groove 115. As illustrated in FIG. 1B, the gate dielectric pattern 125 has a U-shaped cross section. Furthermore, the gate dielectric pattern 125 may be of at least one material selected from the group consisting of an oxide, nitride, oxynitride and high-k dielectric material. In this specification, a high-k dielectric material generally refers to an insulating material having a dielectric constant higher than that of a nitride, e.g., a metal oxide such as hafnium oxide or aluminum oxide.

The active regions 103 have first impurity regions 107a and second impurity regions 107b. The bottom surfaces of the first and second impurity regions 107a and 107b may be located at a level above that of the bottom surfaces of the grooves 115. In this embodiment, a pair of the grooves 115 crosses each active region 103. In this case, each active region 103 includes a pair of the first impurity regions 107a and a second impurity region 107b. The pair of buried gate electrodes 133 and the second impurity doping region 107b are interposed between the pair of first impurity doping regions 107a, and the second impurity region 107b is interposed between the pair of buried gate electrodes 133.

A capping pattern 135 may be disposed on each buried gate electrode 133 such that capping patterns 135 disposed on the pair of pair of buried gate electrodes 133, respectively, are spaced from each other in the second direction. The capping pattern 135 is of insulating material. For example, the capping pattern 135 is of at least one of an oxide, nitride and oxynitride. Furthermore, each capping pattern 135 may occupy part of the groove 115 in which the buried gate electrode 133 is disposed. The capping pattern 135 thus also has a linear shape in the first direction when viewed in plan. In the illustrated example of this embodiment, the top surface of the capping pattern 135 is disposed at a level above the top surface of the substrate 100. Furthermore, the capping pattern 135 may be a single- or multi-layered structure.

The semiconductor device also has conductive lands (“pads” hereinafter) 145 on the substrate 100. Each pad 145 may include first sidewalls extending in the first direction and facing each other and second sidewalls extending in the second direction and facing each other. Furthermore, each pad 145 is electrically connected to a first impurity region 107a. In the illustrated example, a part of the pad 145 contacts the first impurity doping region 107a.

Also, in this example, the top surfaces of the pads 145 are even with the top surfaces of the capping pattern 135. That is, the height H1 of the capping patterns 135, from the top surface of the substrate 100, is equal to the height H2 of the landing pads 145.

An etch-stop film 151 (which is optional) and a first interlayer dielectric film 153 cover the pads 145 and the capping patterns 135. In the case in which an etch-stop film is employed, the etch-stop film 151 is disposed in contact with the capping patterns 135 and the pads 145. Also, the etch-stop film 151 may be of at least one material selected from the group consisting of a silicon oxide, a silicon nitride and a silicon oxynitride. The first interlayer dielectric film 153 may also be of at least one material selected from the group consisting of a silicon oxide, a silicon nitride and a silicon oxynitride. Moreover, in this example, the etch-stop film 151 and the first interlayer dielectric film 153 have an etch selectivity with respect to each other. For example, the etch-stop film 151 may be of silicon nitride and the first interlayer dielectric film 153 may be of silicon oxide.

A plurality of dielectric patterns 163 extend in the second direction on the substrate 100. Each dielectric pattern 163 includes linear portions 163a, and spacer portions 163b each having the shape of a donut (i.e., ring-shaped) when viewed in plan and connected by the linear portions 163a. The dielectric pattern 163 extends through the etch-stop film 151 and the first interlayer dielectric film 153 into contact with several of the active regions 103 (a column of the active regions) and the device isolation pattern 101 therebetween, and thus crosses the rows of active regions 103. The dielectric pattern 163 may include at least one of a silicon oxide, a silicon nitride and a silicon oxynitride.

Each pad 145 is interposed between a pair of adjacent capping patterns 135, and a pair of adjacent dielectric patterns 163. In this respect, the first sidewalls of the landing pad 145 may contact the sidewalls of the capping patterns 135, respectively. The second sidewalls of the landing pad 145 may contact the dielectric patterns 163, respectively. More specifically, the second sidewalls of the landing pad 145 may be disposed between the linear portion 163a of one dielectric pattern 163 and the spacer portion 163b of the other dielectric pattern 163. Thus, the second sidewall which is in contact with the spacer portion 163b is concave.

First contact plugs 165 extend through the etch-stop film 151 and the first interlayer dielectric film 153. In the illustrated example, each first contact plug 165 contacts a second impurity doping region 107b. The first contact plug 165 may be of at least one material selected from the group consisting of semiconductor materials (e.g., polycrystalline silicon), metal-semiconductor compounds (e.g., tungsten silicide), conductive metal nitrides (e.g., titanium nitride, tantalum nitride or tungsten nitride) and metals (e.g., titanium, tungsten or tantalum).

Each first contact plug 165 is disposed in a spacer portion 163b of a dielectric pattern 163. In this example, the first contact plug 165 contacts (the inside of) the spacer portion 163b. Furthermore, the first contact plug 165 is interposed between a pair of the capping patterns 135.

The semiconductor device of this embodiment also has interconnections 170 disposed on the first interlayer dielectric film 153 and the dielectric patterns 163 and electrically connected to the first contact plugs 165. Each interconnection 170 is in the form of a line extending longitudinally in the second direction. The interconnection 170 may contact a column of the first contact plugs 165. The interconnection 170 is of conductive material. For example, the interconnection 170 may be of at least one material selected from the group consisting of semiconductor materials (e.g., polycrystalline silicon), metal-semiconductor compounds (e.g., tungsten silicide), conductive metal nitrides (e.g., titanium nitride, tantalum nitride or tungsten nitride) and metals (e.g., titanium, tungsten or tantalum).

A second interlayer dielectric film 180 is disposed on the first interlayer dielectric film 153 and the dielectric patterns 163 over the interconnections 170. The second interlayer dielectric film 180 may be of an oxide, a nitride or an oxynitride. Also, the second interlayer dielectric film 180 may be a single- multi-layered structure. In this embodiment, the second interlayer dielectric film 180 is of the same material as the first interlayer dielectric film 153.

Second contact plugs 185 extend through the etch-stop film 151, the first interlayer dielectric film 153 and the second interlayer dielectric film 180 and are disposed on and electrically connected to the pads 145, respectively. That is, the second contact plug 185 does not contact the substrate 100. Therefore, according to one aspect of the inventive concept, the device isolation pattern 101 is not over-etched when the second contact plugs 185 are formed. Furthermore, in this respect, the bottoms surfaces of the second contact plugs 185 may be disposed in contact with the pads 145.

Also, each second contact plug 185 may be of at least one material selected from the group consisting of semiconductor materials (e.g., polycrystalline silicon), metal-semiconductor compounds (e.g., tungsten silicide), conductive metal nitrides (e.g., titanium nitride, tantalum nitride or tungsten nitride) and metals (e.g., titanium, tungsten or tantalum).

Parts of each second contact plug 185 and the pad 145 to which the second contact plug 185 is electrically connected lie directly over a first doping region 107a of an active region 103, as shown in FIGS. 1A and 1C. More specifically, with respect to the second contact plug 185, one part of the bottom surface of the second contact plug 185 lies directly over the device isolation pattern 101 and another part of the bottom surface of the second contact plug 185 lies directly over (the first doping region 107a) of the active region 103 of the substrate 100. In this respect, the area of overlap between the second contact plug 185 and the first impurity doping region 107a is smaller than the area of overlap between the landing pad 45 and the first impurity doping region 107a. Thus, the pad 145 secures a greater area for the second contact plug 185 to be electrically connected to the first impurity doping region 107a.

Thus, the semiconductor device is highly reliable and has excellent electrical characteristics. Also, a wide process margin for the second contact plugs 185 can be secured. That is, problems due to misalignment of the second contact plug 185 may be minimized.

The semiconductor device may also have information storage elements 190, as illustrated in FIG. 1C, although the elements are not shown in FIG. 1A for ease of illustration. Each information storage element 190 may be disposed on the second interlayer dielectric film 180 and electrically connected to a second contact plug 185.

FIG. 1D shows an example in which the information storage element 190 is a capacitor. In this example, the capacitor has a storage node 210 connected to the second contact plug 185. More specifically, the storage node 210 have a generally planar portion situated on the second contact plug 185 and a cylindrical side portion extending upwardly from the periphery of the planar portion. The storage node 210 is also of conductive material and in this respect, may include at least one material selected from a group consisting of doped semiconductor materials, conductive metal nitrides (e.g., titanium nitride, tantalum nitride or tungsten nitride), metals (e.g., ruthenium, iridium, titanium, tungsten or tantalum) and conductive metal oxides (e.g., iridium oxide).

The capacitor also has a dielectric film 220 disposed conformally along the interior surfaces of the storage node 210. The dielectric film 220 may be of at least one of an oxide, a nitride, an oxynitride and a high-k dielectric material. The dielectric film 220 may cover the storage node 210 entirely. Also, the dielectric film 220 may cover a portion of top surface of the second interlayer dielectric film 180.

The capacitor also has an upper electrode 230 covering the dielectric film 220. The upper electrode 230 is of conductive material and in this respect, may be of at least one material selected from the group consisting of doped semiconductor materials, metals, conductive metal nitrides and metal silicides.

FIG. 1E shows an example in which the information storage element 190 comprises a variable resistor. More specifically, the information storage element 190 has a first electrode 250, a variable resistor 260 and a second electrode 270. The variable resistor 260 is interposed between the first electrode 250 and the second electrode 270. That is, the first electrode 250, the variable resistor 260 and the second electrode 270 are stacked one atop the other in the foregoing order.

The variable resistor 260 may comprises phase change material. The phase change material may comprise Te and/or Se (chalcogenide element(s)) and a compound including at least one of Ge, Sb, Bi, Pb, Sn, Ag, As, S, Si, P, O, and N. More specifically, the variable resistor 260 may comprise at least one compound selected from the group consisting of Ge—Sb—Te, As—Sb—Te, Ag—In—Sb—Te, In—Sb—Te, 5A group element-Sb—Te, 6A group element-Sb—Te, 5A group element-Sb—Se, and 6A group element-Sb—Se.

The first electrode 250 and the second electrode 270 preferably are of conductive materials having low reactivity. For instance, the first electrode 250 and the second electrode 270 may each comprise a conductive metal nitride (e.g., may each comprise titanium nitride, tantalum nitride and/or titanium-aluminum nitride). In the example shown in FIG. 1E, the first electrode 250 is a heat electrode meaning that is serves to transfer heat to/from the variable resistor 260, to change the state of the variable resistor 260 between an amorphous state and a crystalline state. The difference between the resistivity of the variable resistor 260 when the variable resistor 260 is an amorphous state and the resistivity of the variable resistor 260 when the variable resistor 260 is in a crystalline state is used as the mechanism for storing/recording different data.

Although not illustrated, the information storage element 190 may also include an ohmic layer interposed between the second contact plug 185 and the first electrode 250. In this case, the ohmic layer preferably comprises a metal-semiconductor compound. For instance, the ohmic layer may includes at least one compound selected from the group consisting of cobalt-semiconductor compounds (e.g., cobalt silicide), nickel-semiconductor compounds (e.g., nickel silicide) and titanium-semiconductor compounds (e.g., titanium silicide).

Alternatively, the variable resistor 260 may comprise a transition metal oxide. For instance, the variable resistor 260 may comprise at least one of nickel (Ni), niobium (Nb), titanium (Ti), zirconium (Zr), hafnium (Hf), cobalt (Co), ferrum (F), and copper (Cu).

In this case, the first electrode 250 and the second electrode 270 are of conductive materials. For instance, the first and second electrodes 250 and 270 may each comprise at least one of aluminum (Al), gold (Au), platinum (Pb), ruthenium (Ru), iridium (Ir) and titanium (Ti). In this case, the information storage element 190 stores information based on the value of the resistance of the variable resistor 260 which changes depending on the voltage applied to the first electrode 250 and the second electrode 270.

As another example, the variable resistor 260 may be a magnetic tunnel junction pattern (MTJ). In this case, the variable resistor 260 has a free layer and a reference layer, and a tunnel barrier interposed between the free layer and the reference layer. The direction of magnetization of the free layer is changeable, and the direction of magnetization of the reference layer is fixed.

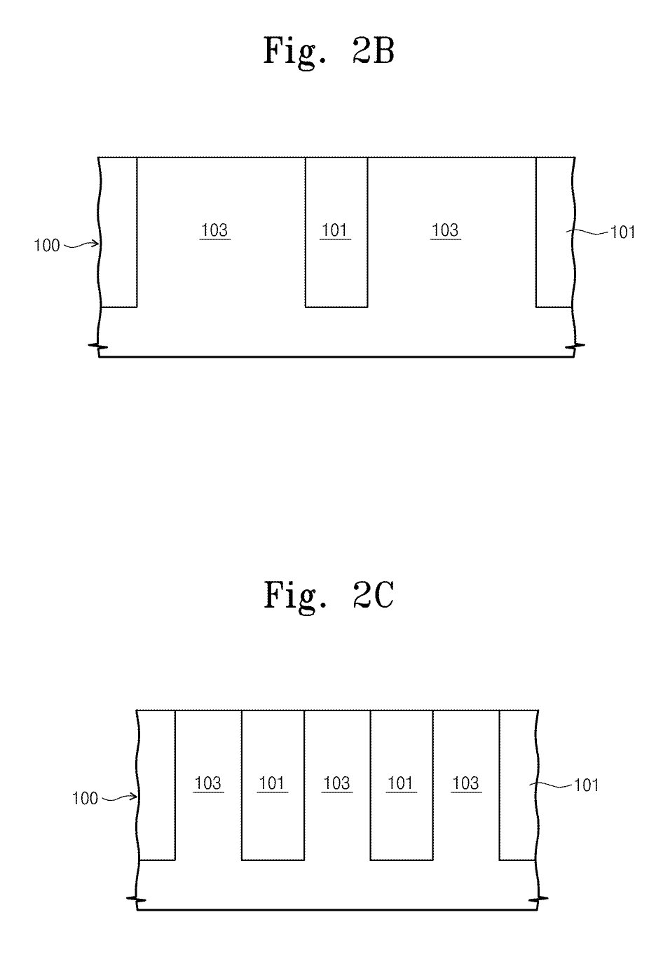

Hereinafter, a method of forming a semiconductor memory device, in accordance with the inventive concept, will be described with reference to FIGS. 2A and 2B through FIGS. 18A and 18B. For some details of the structures formed by the steps described below, reference may be had to the previous detailed description made with reference to FIGS. 1A-1E.

Referring to FIGS. 2A, 2B and 2C, device isolation pattern 101 defining active regions 103 is formed in a substrate 100. Specifically, an etching mask is formed on the substrate 100, the substrate 100 is etched using the etching mask to form trenches in the substrate, and the trenches are filled with insulating material to form the device isolation pattern 101.

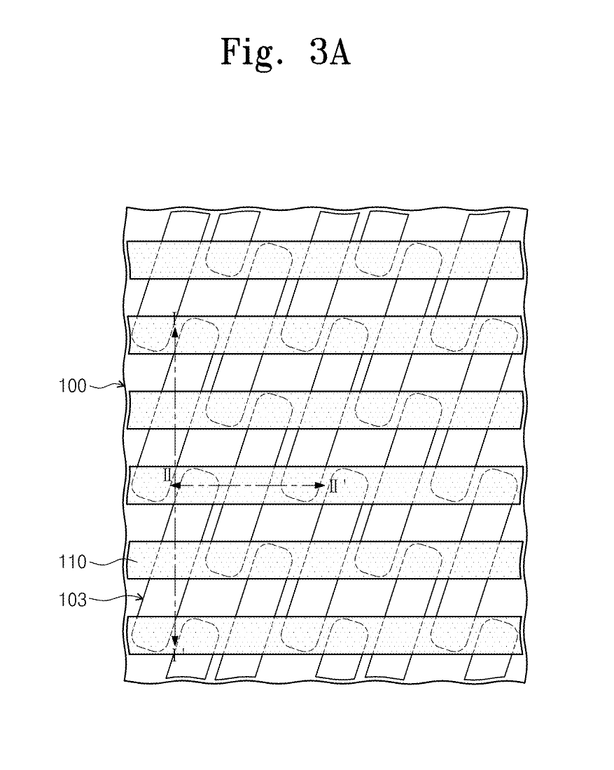

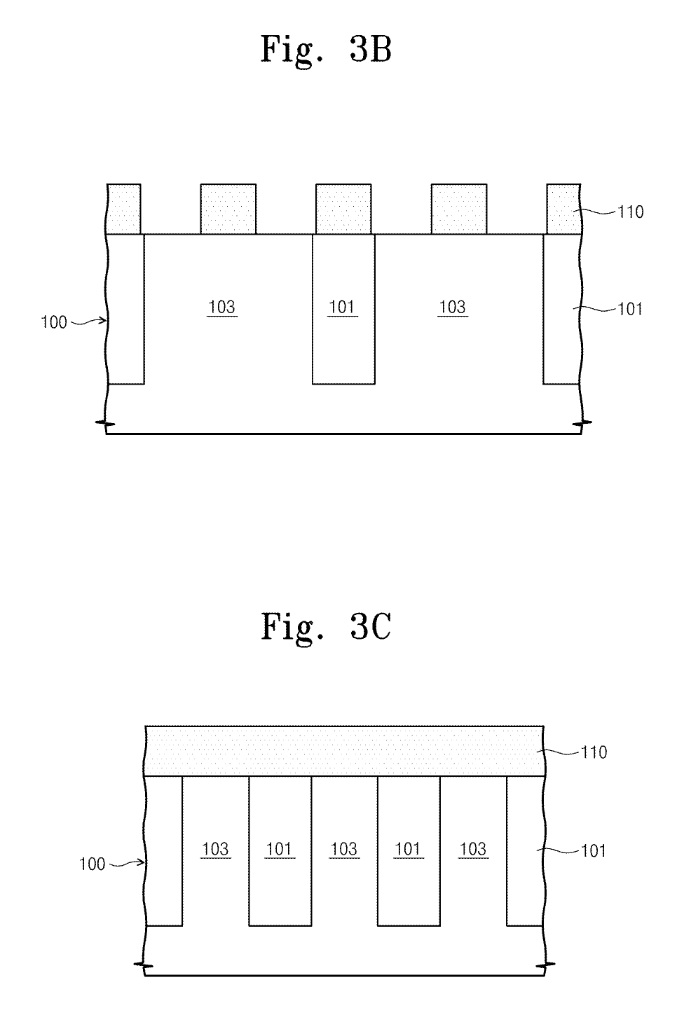

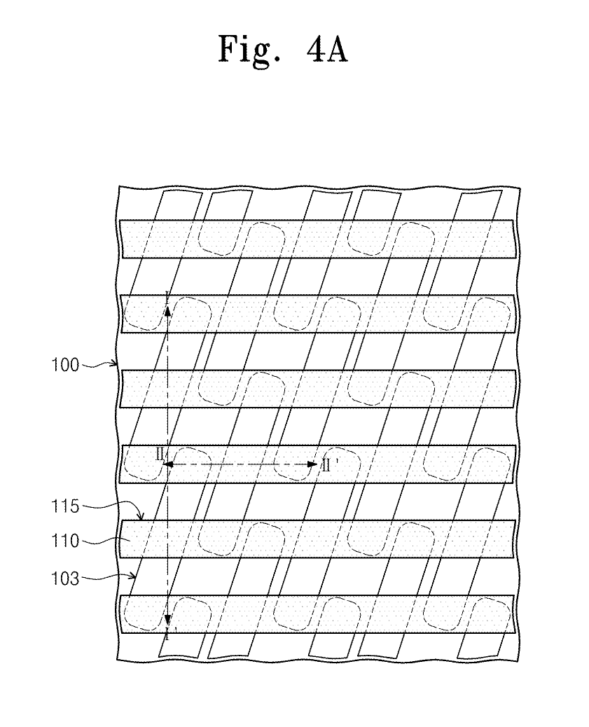

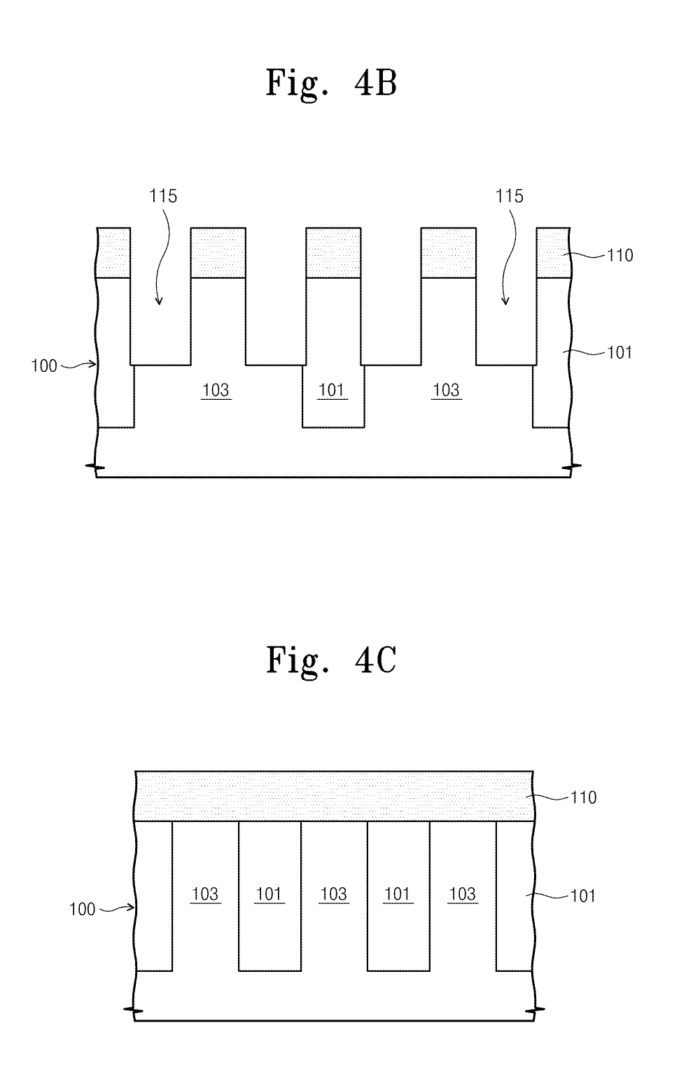

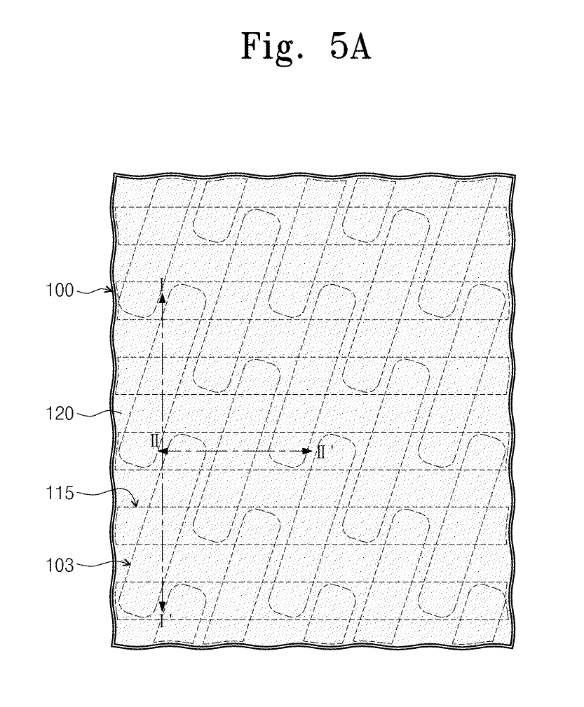

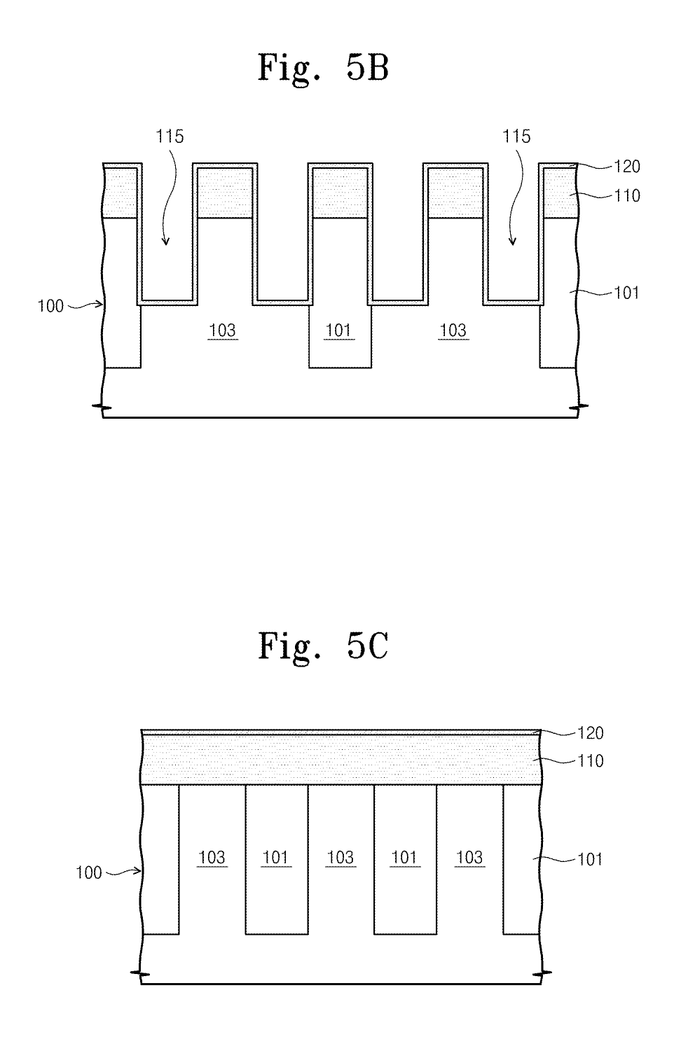

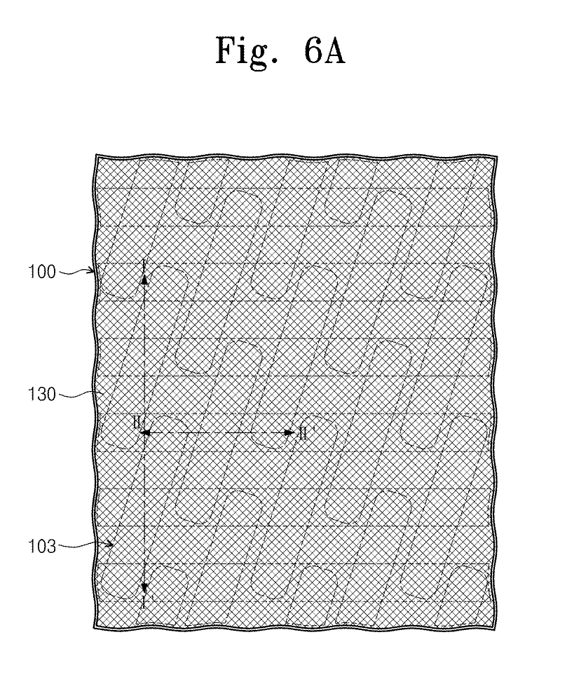

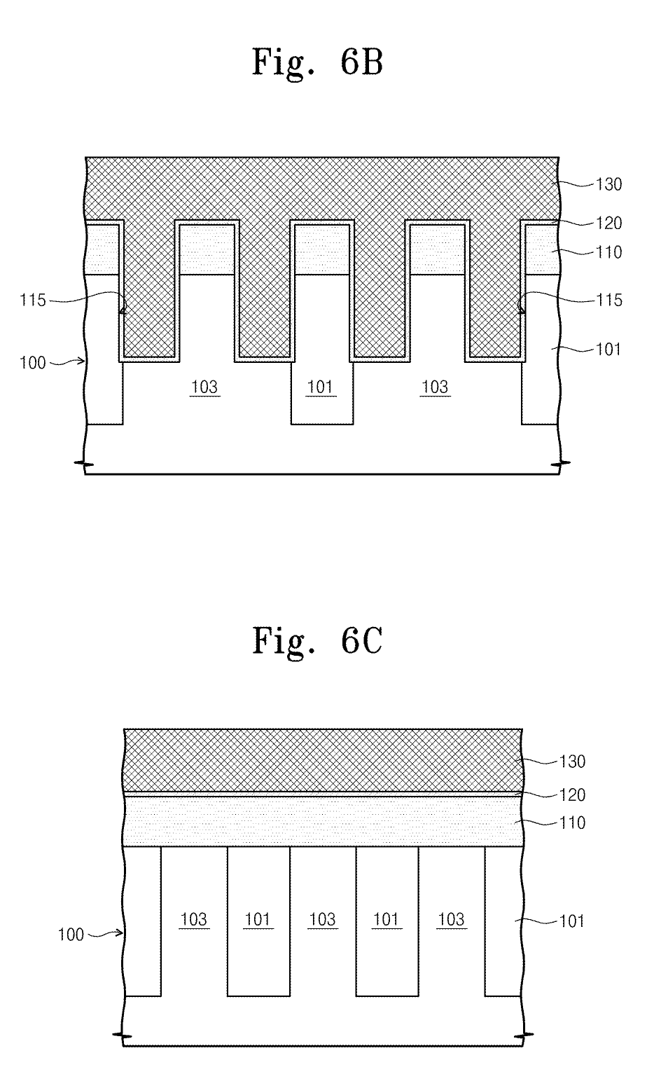

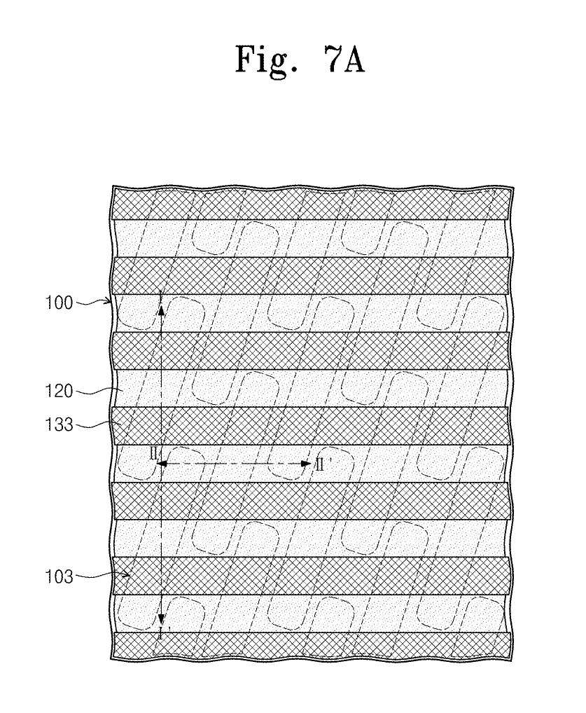

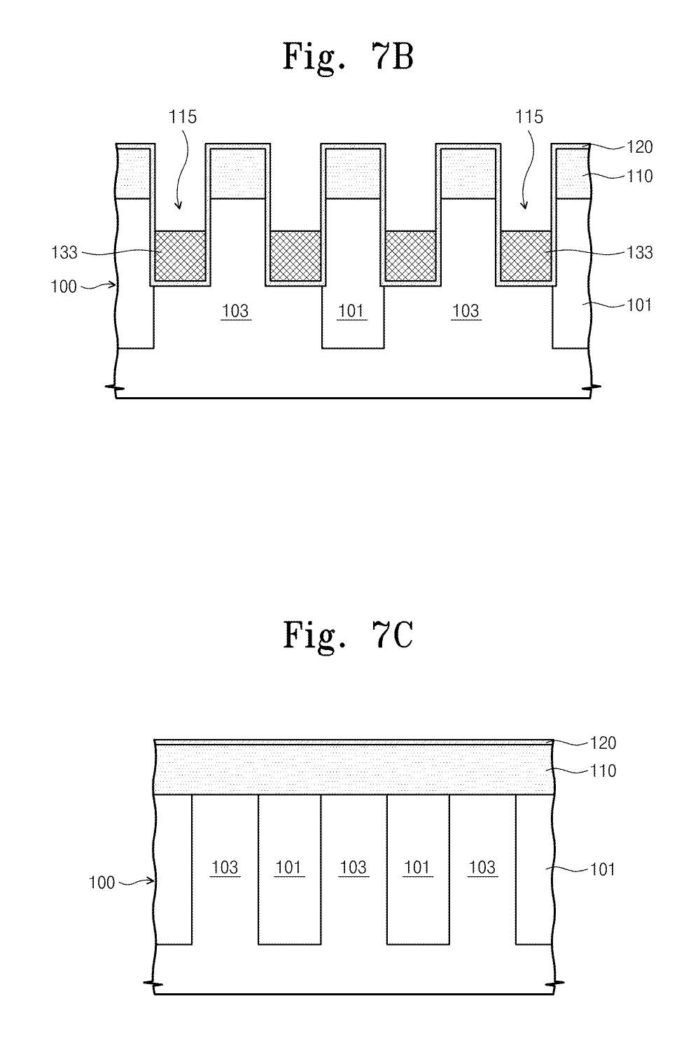

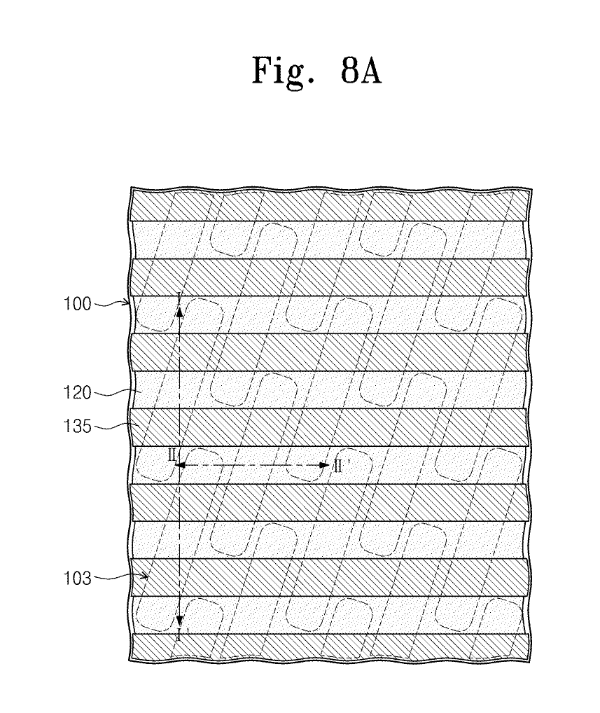

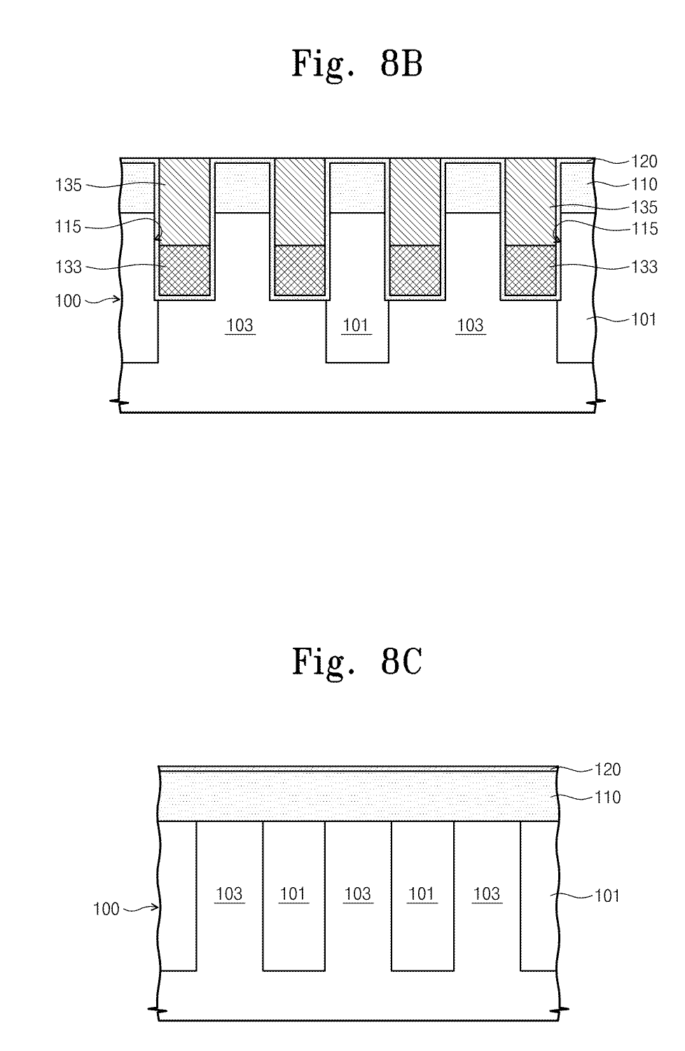

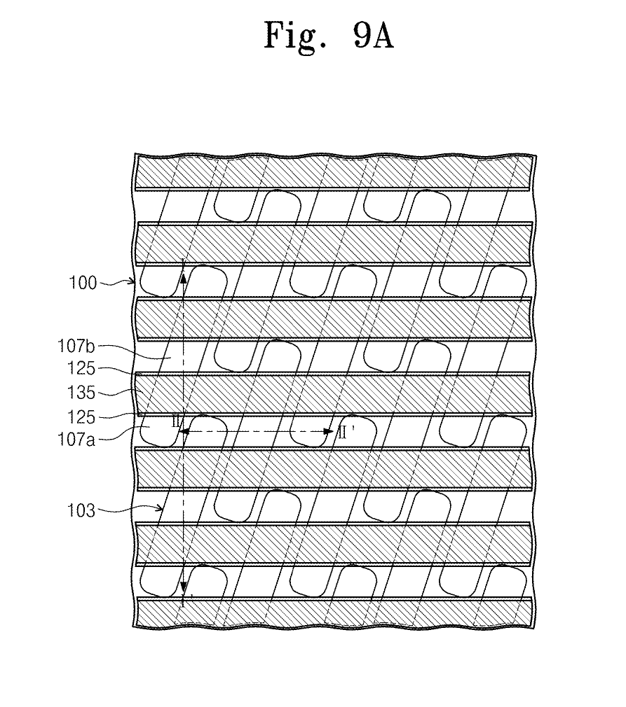

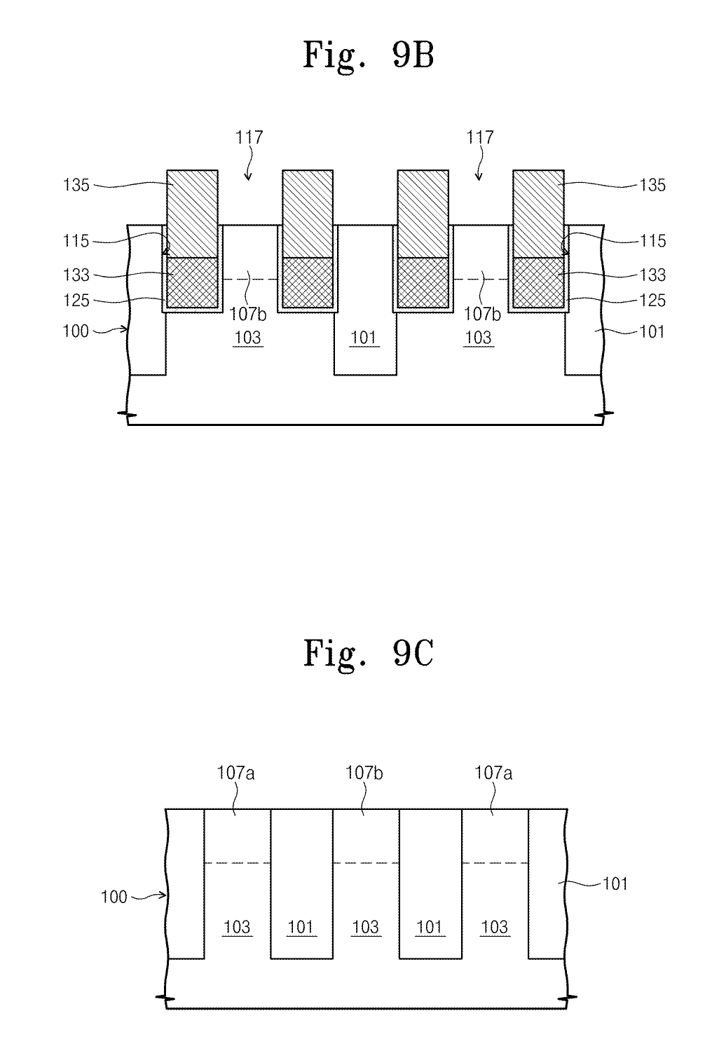

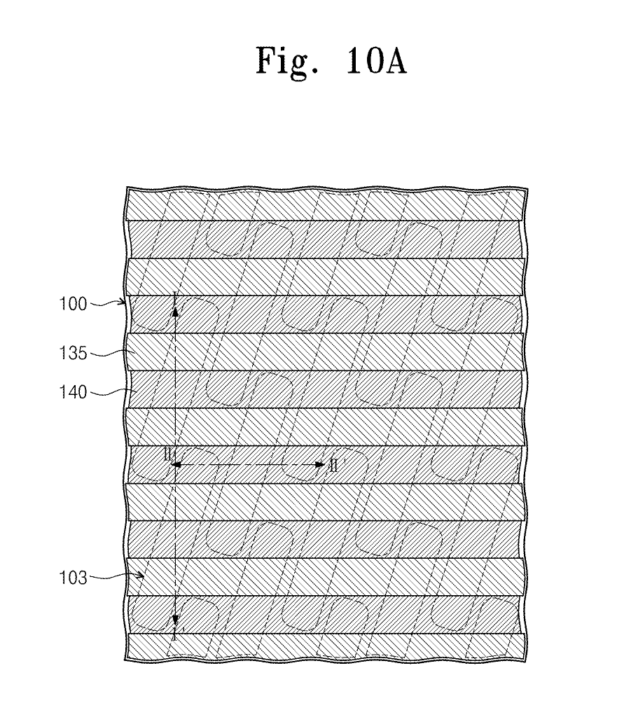

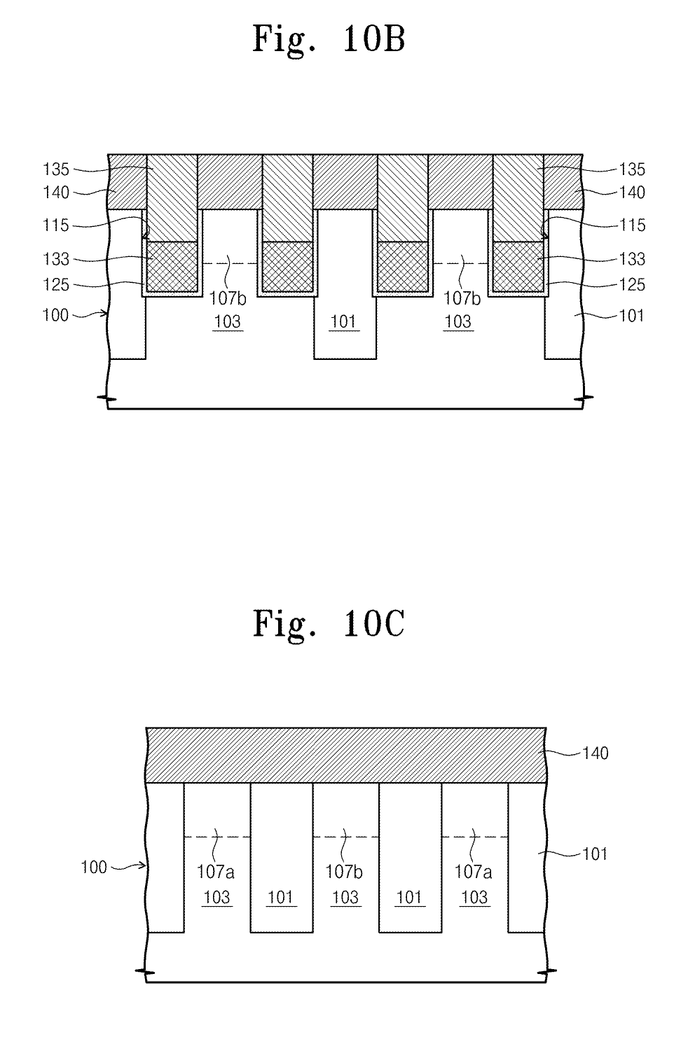

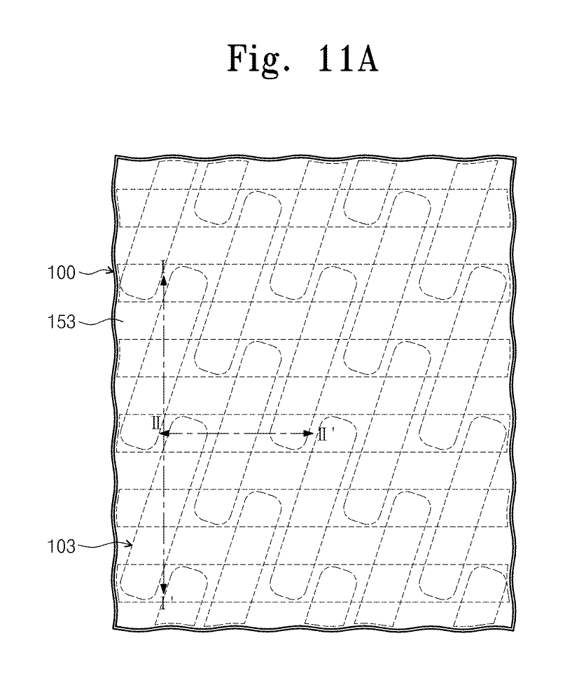

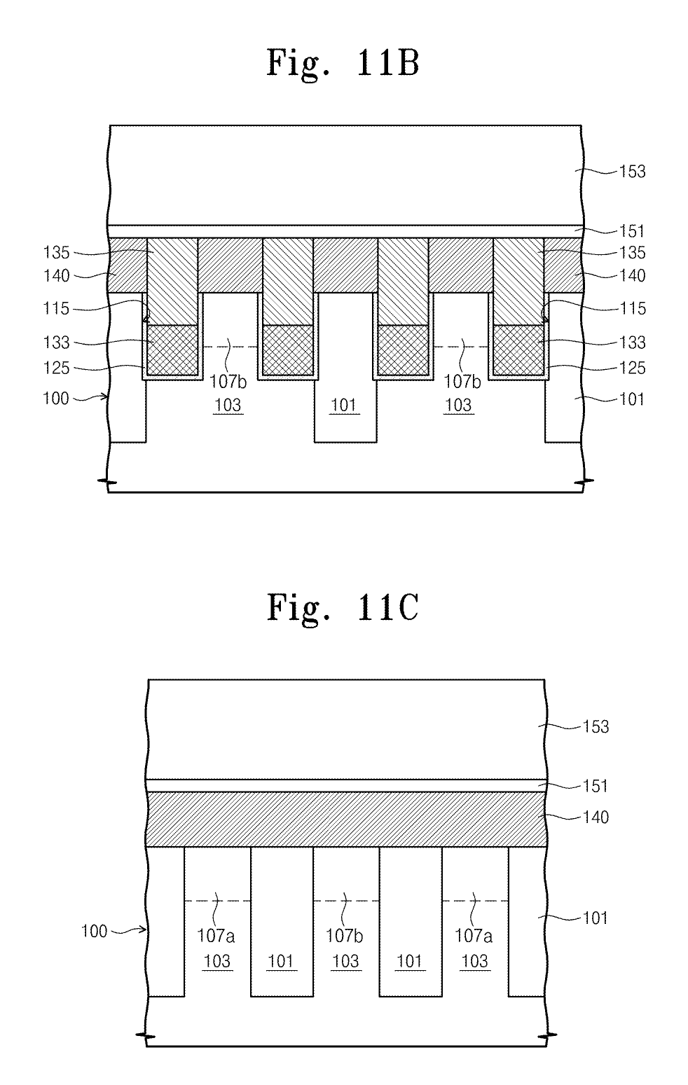

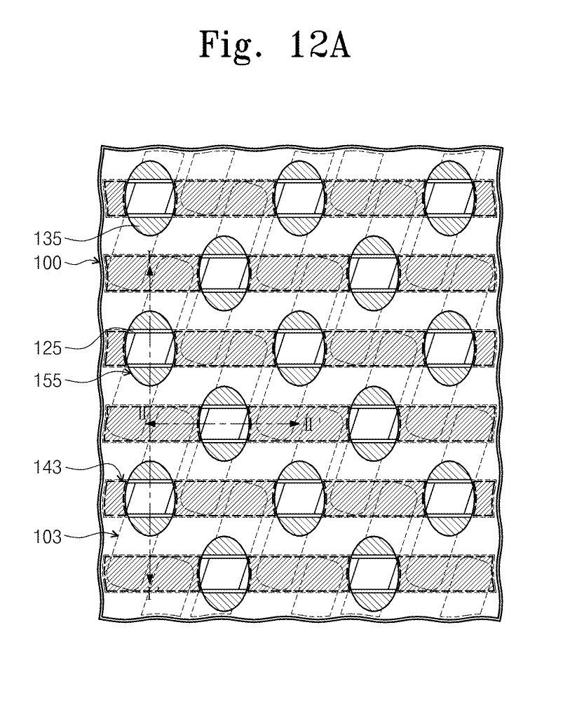

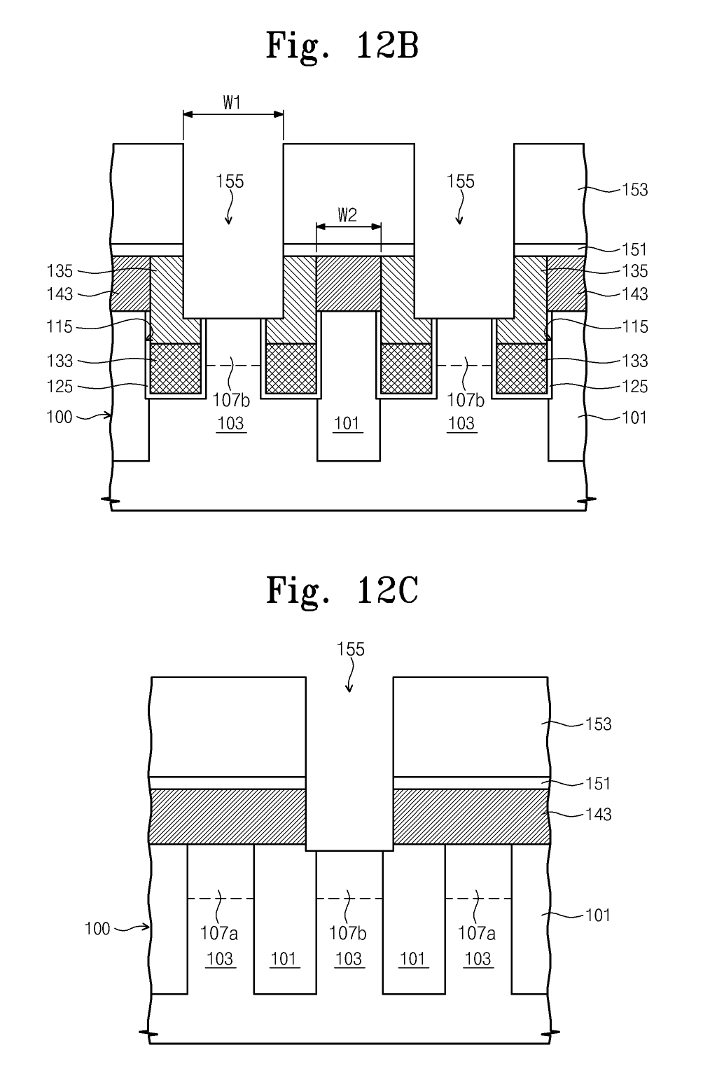

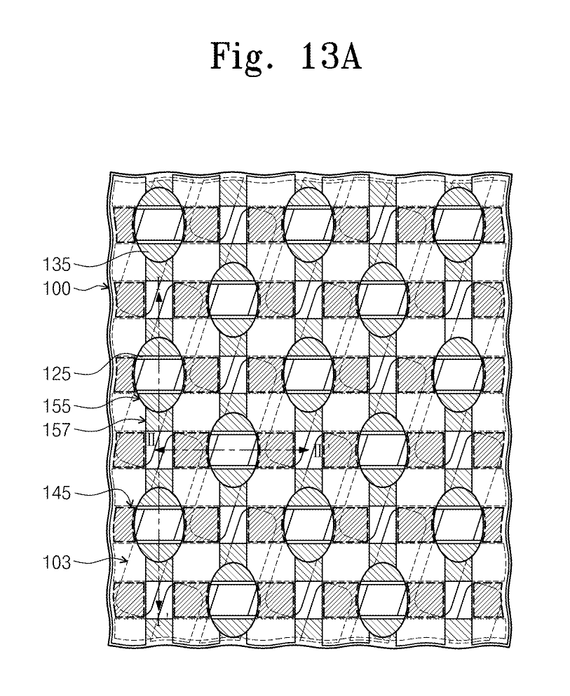

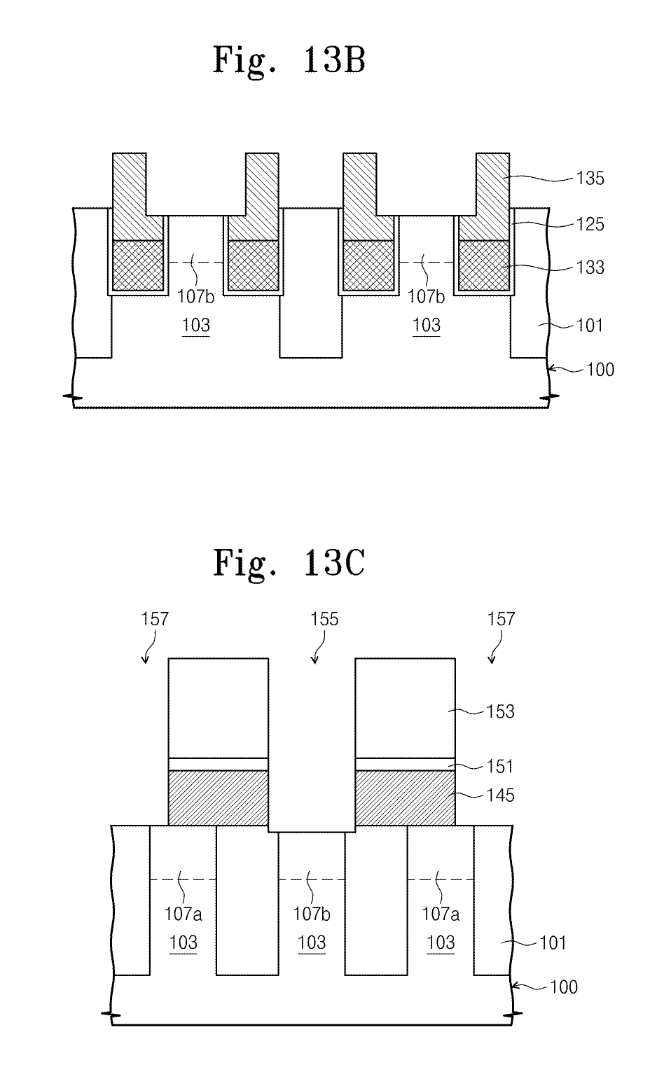

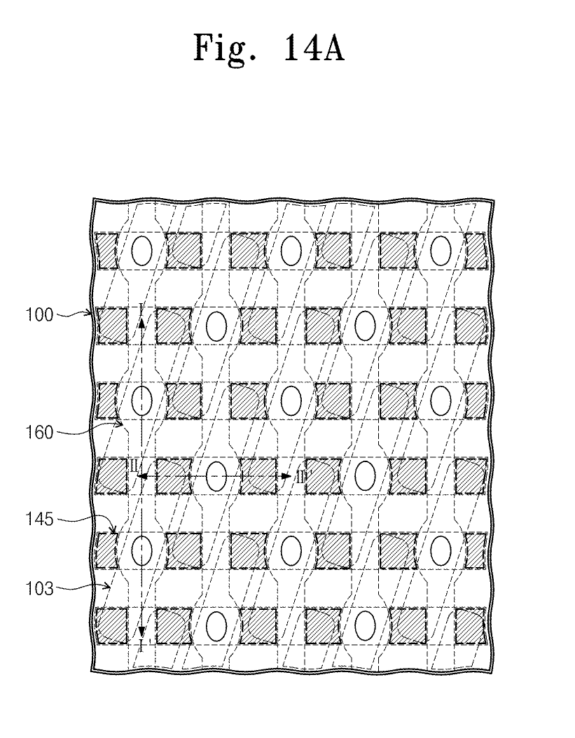

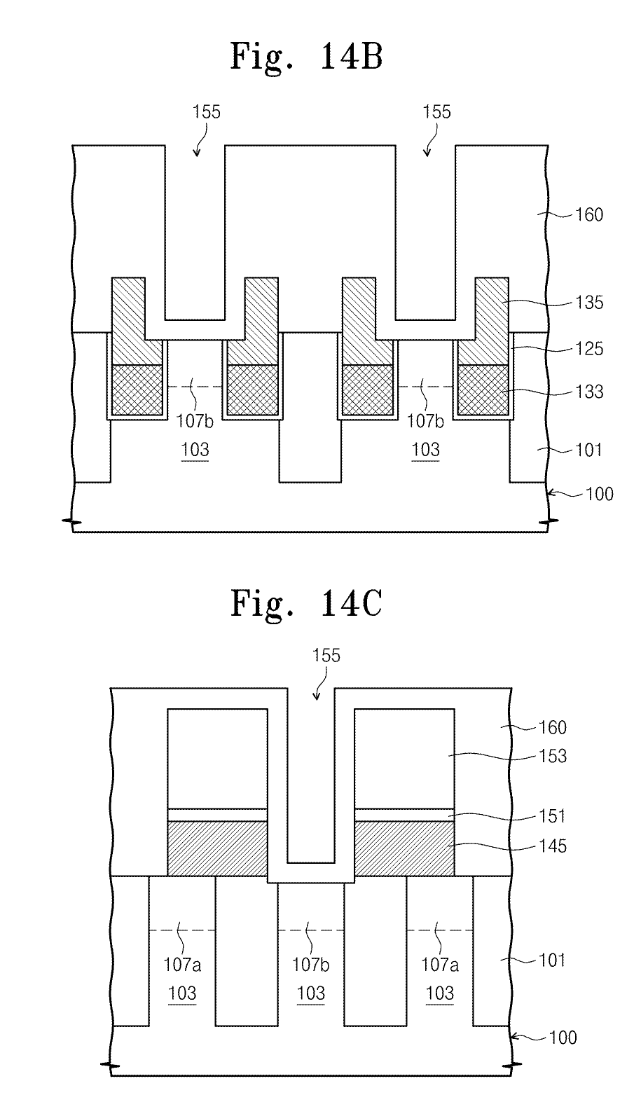

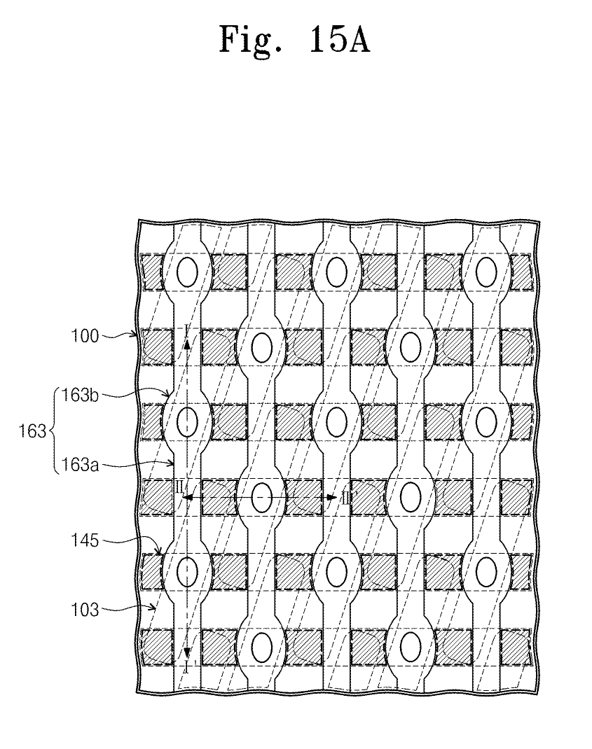

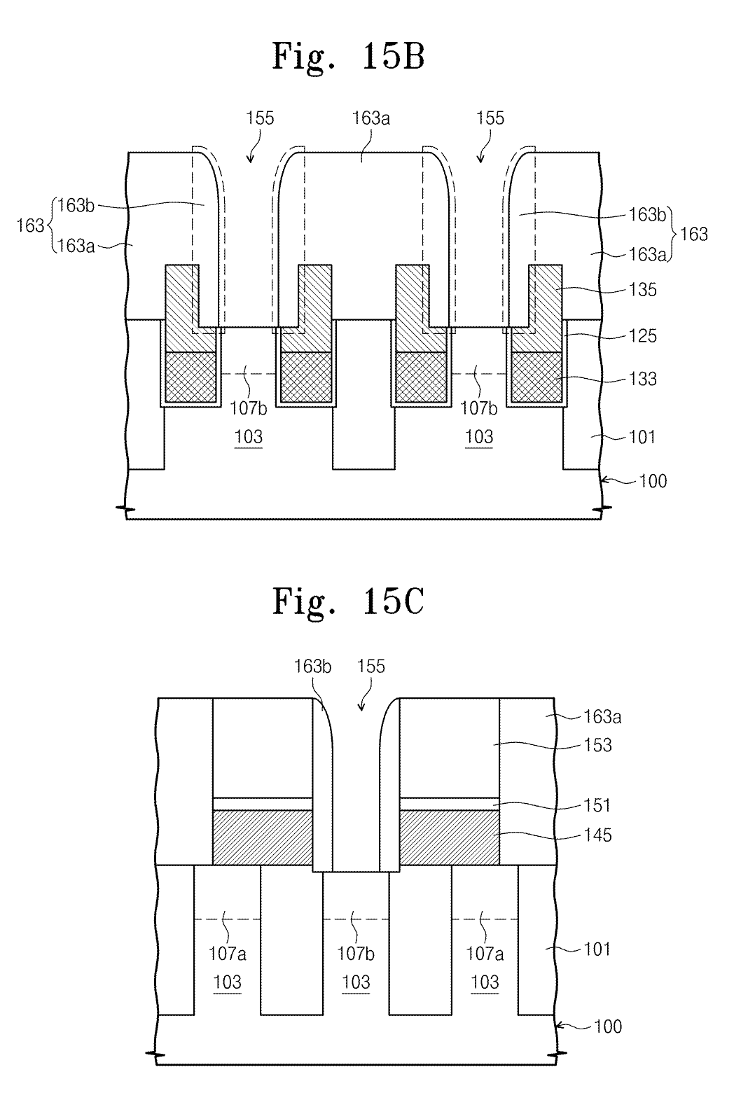

Referring to FIGS. 3A, 3B and 3C, a mask 110 having a line and space pattern is formed on the substrate 100. More specifically, the mask 110 has linear sections extending in the first direction and crossing the active regions 103 and the device isolation pattern 101. The mask may be formed by forming a film on the substrate 100 and patterning the film.

The film may be a single or multi-layered film. Each film of the mask can be formed by physical vapor deposition (PVD), chemical vapor deposition (CVD) or a spin coating process. Also, the mask 110 may be formed of at least one of a film of a silicon oxide, a silicon nitride, a silicon oxynitride, a photo resist, and a spin on glass (SOG), and a spin on hard mask (SOH).

Referring to FIGS. 4A, 4B and 4C, grooves 115 are formed in the substrate using the mask 110 as an etching mask. In particular, each groove 115 is formed by dry etching the substrate 100 using a pair of the linear segments of the mask 110 as an etching mask. The grooves 115 each extend linearly in the first direction across several of the active regions 103 and the device isolation pattern 101 therebetween.

Referring to FIGS. 5A, 5B and 5C, a gate dielectric film 120 is conformally formed on the substrate 100 so as to extend on the top surface of the substrate 100 and within the grooves 115. The gate dielectric film 120 may be formed by an oxidation process. In this case, the oxidation process may be performed in one or more stages. Alternatively, the gate dielectric film 120 may be formed by a chemical vapor deposition (CVD) process or an atomic layer deposition (ALD) process.

Referring to FIGS. 6A, 6B and 6C, next, gate conductive film 130 is formed on the substrate 100.

The gate conductive film 130 may be formed by a physical vapor deposition (PVD) process, a chemical vapor deposition (CVD) process or an atomic layer deposition (ALD) process, to fill the grooves 115. The gate conductive film 130 can be formed from a semiconductor material that is doped, a conductive metal nitride (e.g., titanium nitride, tantalum nitride or tungsten nitride) and/or a metal (e.g., ruthenium, iridium, titanium, tungsten or tantalum).

Alternatively, the gate conductive film 130 may be formed conformally forming a conductive liner on the substrate 100 including over surfaces that delimit the grooves 115, and the forming a bulk conductive film on the liner to fill what remains of the grooves 115. The liner and bulk conductive film are preferably formed of materials having an etch selectivity with respect to each other. For instance, the liner may comprise a titanium nitride and the bulk conductive film may comprise tungsten.

Referring to FIGS. 7A, 7B and 7C, the gate conductive film 130 is etched to form buried gate electrodes 133 in the grooves 115, respectively. Each buried gate electrode 133 thus extends longitudinally in the first direction. The etching process may be carried out until a top surface of the buried gate electrode 133 is disposed at a level beneath that of the top surface of the substrate 100. A dry etching process and/or a chemical mechanical polishing (CMP) process can be used to form the buried gate electrodes 133.

In the case in which the gate conductive film 130 is formed by forming a conductive liner and bulk conductive film, each buried gate electrode 133 includes a corresponding liner and a bulk electrode. In this case, the liner of the buried gate electrode 133 has a U-shaped cross section. Also, the liner and bulk electrode may be formed such that their tops surfaces are flush and located at a lower level beneath that of the top surface of the substrate 100.

Referring to FIGS. 8A, 8B and 8C, capping patterns 135 filling what remains of the grooves 115 are formed on the buried gate electrodes 133, respectively. The capping patterns 135 may be formed by forming a capping layer over the entire top surface of the substrate 100 and then etching the capping layer until the gate dielectric film 120 or the top surface of the mask 110 is exposed. In this case, the top surfaces of the capping patterns 135 are even with the top surface of the mask 110. The capping layer may be formed by a physical vapor deposition (PVD) process or a chemical vapor deposition (CVD) process. The etching process may be at least one of a chemical mechanical polishing (CMP) process, a dry etching process and a wet etching process. Also, that part of the gate dielectric film 120 disposed on top of the mask 110 may be removed by the etching process at this time.

Referring to FIGS. 9A, 9B and 9C, the mask 110 and the gate dielectric film 120 between the capping patterns 135 are removed by a dry etching process and/or a wet etching process to form spaces 117 between the capping patterns 135, where the active regions 103 and the device isolation pattern 101 are exposed. As a result, a gate dielectric pattern 125 is formed in each groove 115 around the buried gate electrode 133 disposed in the groove. The gate dielectric pattern 125 has a U-shaped cross section.

First impurity regions 107a and second impurity regions 107b are formed by implanting impurities into the exposed portions of the active regions 103. The first impurity regions 107a are formed in the active regions 103 adjacent first sides (or ends) of the buried gate electrodes 133 and the second impurity regions 107b are formed in the active regions 103 adjacent second sides of the buried gate electrodes 133. The implantation process may be controlled such that the first and second impurity regions 107a and 107b are formed to a depth above that to which the buried gate electrodes 133 are formed in the substrate.

Referring to FIGS. 10A, 10B and 10C, conductive patterns 140 are formed in the spaces 117, respectively. The conductive pattern 140 is formed by forming a conductive film on the substrate 100 and then etching the conductive film until the capping patterns 135 are exposed. The conductive film may be formed by at least one of a physical vapor deposition (PVD) process, a chemical vapor deposition (CVD) process and an atomic layer deposition (ALD) process. Also, the conductive film may be etched by at least one of a chemical mechanical polishing (CMP) process, a dry etching process and a wet etching process. The conductive patterns 140 may be formed of at least one material selected from the group consisting of semiconductor materials (e.g., polycrystalline silicon), metal-semiconductor compounds (e.g., tungsten silicide), conductive metal nitrides (e.g., titanium nitride, tantalum nitride or tungsten nitride) and metals (e.g., titanium, tungsten or tantalum).

Referring to FIGS. 11A, 11B and 11C, etch-stop film 151 and first interlayer dielectric film 153 are formed on the substrate 100. The etch-stop film 151 and the first interlayer dielectric film 153 may be formed by a physical vapor deposition (PVD) process, a chemical vapor deposition (CVD) process or an atomic layer deposition (ALD) process. In an example of this method, the etch-stop film 151 and the first interlayer dielectric film 153 are formed of materials having an etching selectivity with respect to each other. For instance, the etch-stop film 151 may be formed of a silicon nitride and the first interlayer dielectric film 153 may be formed of a silicon oxide. However, as was mentioned above, the etch-stop film 151 is optional and so, the method may be performed with forming the etch-stop film 151.

Referring to FIGS. 12A, 12B and 12C, the first interlayer dielectric film 153, the etch-stop film 151 and the conductive pattern 140 are sequentially etched, by one or more etching processes, to form first holes 155 each extending through the first interlayer dielectric film 153, the etch-stop film 151 and a conductive pattern 140 so as to expose a second impurity doping region 107b. According to the illustrated example of this embodiment, the width W1 of the first hole 155 is greater than the width W2 of the conductive pattern 140 (the widths being the dimension in the second direction). Also, at this time, a part of each capping pattern 135 is etched. Therefore, the bottom of the first hole 155 is defined by the top surface of the substrate 100 and upwardly facing lower surfaces of a pair of the etched capping patterns 135. Furthermore, preliminary pads 143 are formed by the etching of the conductive pattern 140. More specifically, preliminary pads 143 are each formed between first holes 155 that are adjacent to each other in the first direction.

Referring to FIGS. 13A, 13B and 13C, the first interlayer dielectric film 153, the etch-stop film 151 and the preliminary pads 143 are sequentially patterned to form openings 157 which expose the substrate 100 and the capping patterns 135, and pads 145 electrically connected to the first impurity regions 107a, respectively. The patterning process may comprise a dry etching process carried out in one or more similar stages. Each opening 157 is linear in the second direction when viewed in plan. Also, the opening 157 is open to sides of respective ones of the first holes 155. Thus, each opening 157 connects first holes 155 adjacent to each other in the second direction.

Each landing pad 145, as has been described above, has first sidewalls facing one another and extending in the first direction and second sidewalls facing one another and extending in the second direction. The first sidewalls of the landing pad 145 contact sidewalls of a pair of adjacent capping patterns 135. Furthermore, each landing pad 145 is formed between a first hole 155 and the opening 157 closest thereto in the first direction. Thus, the second sidewall which was formed by the forming of the first hole 155 is concave.

Referring to FIGS. 14A, 14B and 14C, a dielectric film 160 is then formed on the substrate 100 by a physical vapor deposition (PVD) process, a chemical vapor deposition (CVD) process or an atomic layer deposition (ALD) process to fill the openings 157, cover the first interlayer dielectric film 153, and conform to the first holes 155.

Referring to FIGS. 15A, 15B and 15C, the dielectric film 160 is then etched until the first interlayer dielectric film 153 and the substrate 100 are exposed to form dielectric patterns 163 each including linear portions 163a and spacer portions 163b. The dielectric pattern 163 may be formed by an etch-back process using plasma. The linear portions 163a and spacer portions 163b are connected to each other because the openings 157 and the first holes 155, in which they are formed, are connected to each other.

Referring to FIGS. 16A, 16B and 16C, first contact plugs 165 are then formed in (what remains of) the first holes 155, respectively. Thus, each first contact plug 165 is electrically connected to a second impurity doping region 107b. In this example, the first contact plug 165 is formed in contact with the second impurity doping region 107b. Also, the sides of the first contact plug 165 may contact the inside of the spacer portion 163b.

The first contact plug 165 can be formed by forming a conductive film on the dielectric pattern 163 and the first interlayer dielectric film 153 to such a thickness as to fill the first holes 155, and then etching the conductive film until the dielectric pattern 163 and the first interlayer dielectric film 153 are exposed. The conductive film may be formed by a physical vapor deposition (PVD) process, a chemical vapor deposition (CVD) process or an atomic layer deposition (ALD) process. The conductive film may be etched by at least one of a dry etching process and a chemical mechanical polishing process (CMP).

Referring to FIGS. 17A. 17B and 17C, next, interconnections 170 are formed on the dielectric pattern 163 and the first interlayer dielectric film 153, each in contact with the first contact plugs 165 of a respective column. The interconnection 170 can be formed by forming a conductive film on the dielectric pattern 163 and the first interlayer dielectric film 153 and then patterning the conductive film. In this case, as well, the conductive film may be formed by a physical vapor deposition (PVD) process, a chemical vapor deposition (CVD) process or an atomic layer deposition (ALD) process. The interconnection conductive film may be formed of at least one material selected from the group consisting of semiconductor materials (e.g., polycrystalline silicon), metal-semiconductor compounds (e.g., tungsten silicide), conductive metal nitrides (e.g., titanium nitride, tantalum nitride or tungsten nitride) and metals (e.g., titanium, tungsten or tantalum).

Alternatively, the interconnections 170 may be formed by a damascene process. That is, the interconnections 170 may be formed by forming a mold layer on the dielectric pattern 163 and the first interlayer dielectric film 153 and then filling the mold layer with conductive material.

Referring to FIGS. 18A, 18B and 18C, second interlayer dielectric film 180 is formed on the dielectric pattern 163 and the first interlayer dielectric film 153 over the interconnections 170. The second interlayer dielectric film 180 may be formed of at least one of a silicon oxide, a silicon nitride and a silicon oxynitride by a physical vapor deposition (PVD) process, a chemical vapor deposition (CVD) process or an atomic layer deposition (ALD) process.

Referring back to FIGS. 1A, 1B and 1C, second contact plugs 185 are then formed in the second interlayer dielectric film 180, the first interlayer dielectric film 153 and the etch-stop film. First, second holes 183 are formed by sequentially etching the second interlayer dielectric film 180, the first interlayer dielectric film 153 and the etch-stop film 151, and the second holes 183 are filled with conductive material. The etching process used to form the second holes 183 may be a dry etching process carried out in one or more stages.

Basically, the dry etching process is carried out until the top surfaces of the pads 145 are exposed. Therefore, the etching process does not expose the active regions 103 or the device isolation pattern 101 and hence, the potential for the over-etching of the device isolation pattern 101 and the problems associated therewith are avoided. Also, the second contact plug 185 is formed on the landing pad 145 which is wider than the second contact plug and thus, a relatively large process margin for the forming of the second contact plug 185 is secured. That is, problems due to a misalignment of the second contact plug 185 with (the first impurity region 107a) of the active region 103 are avoided. Thus, a semiconductor memory device formed according to an example of this method has an excellent reliability and excellent electrical characteristics.

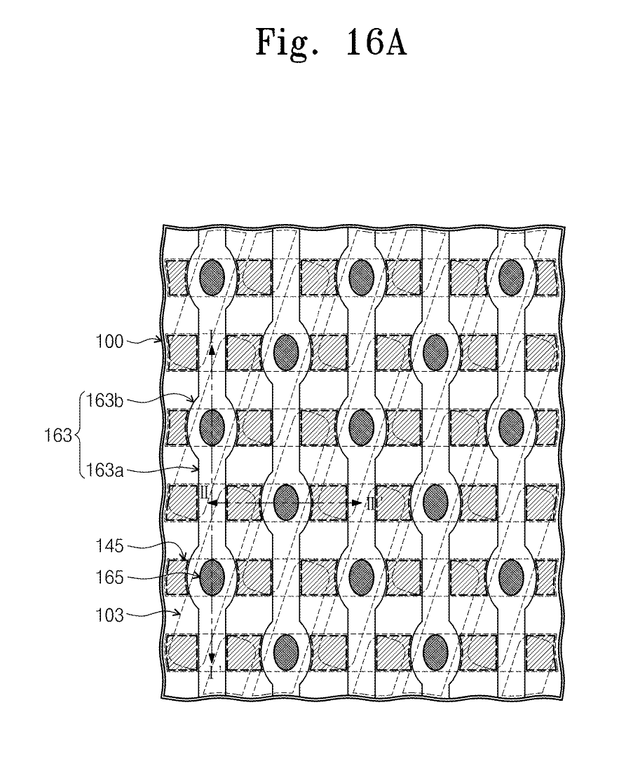

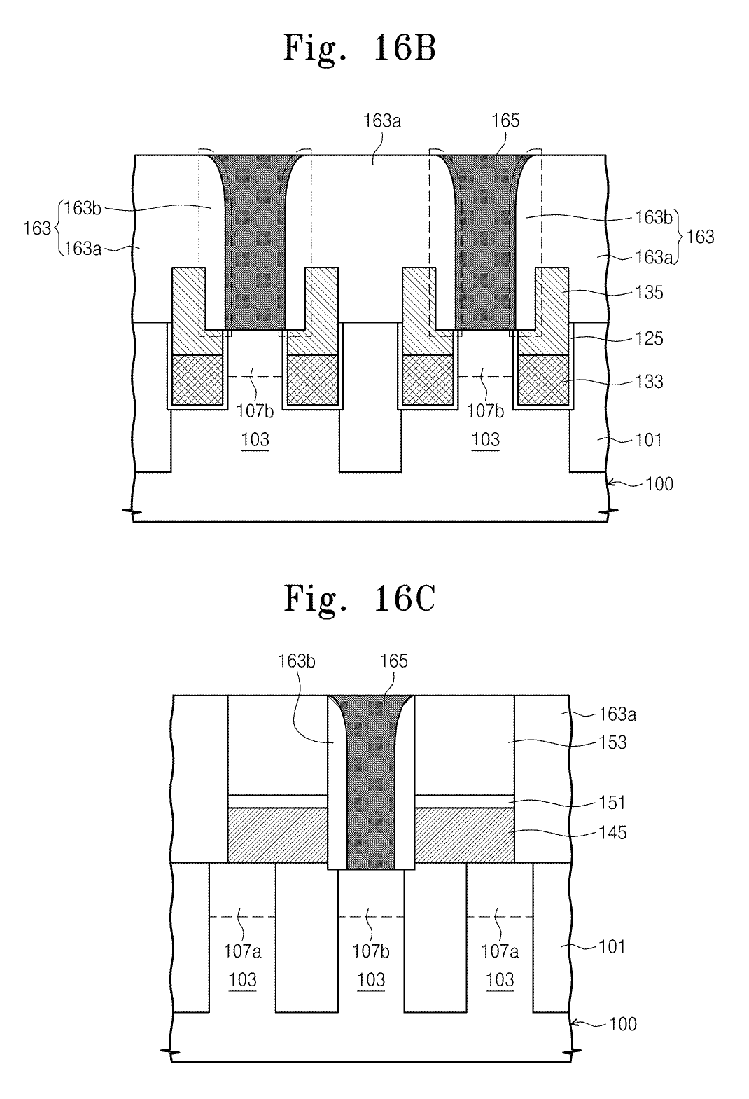

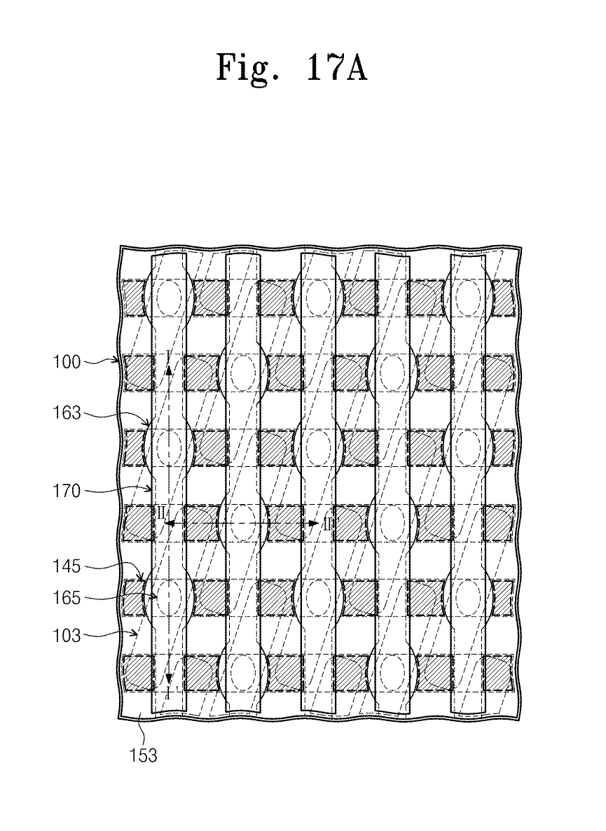

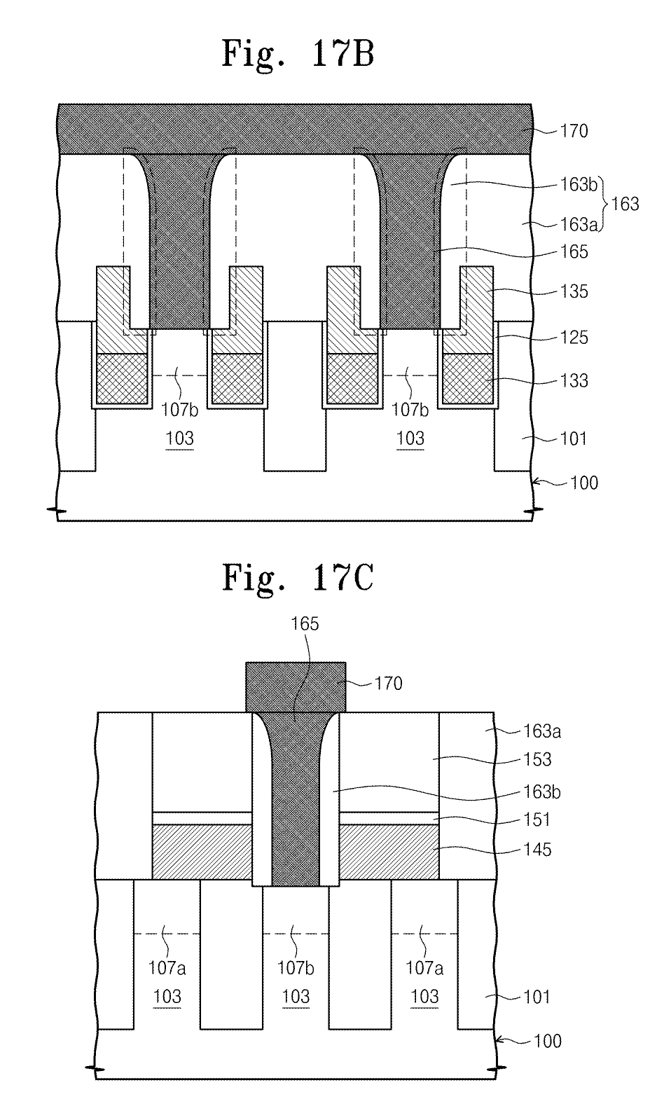

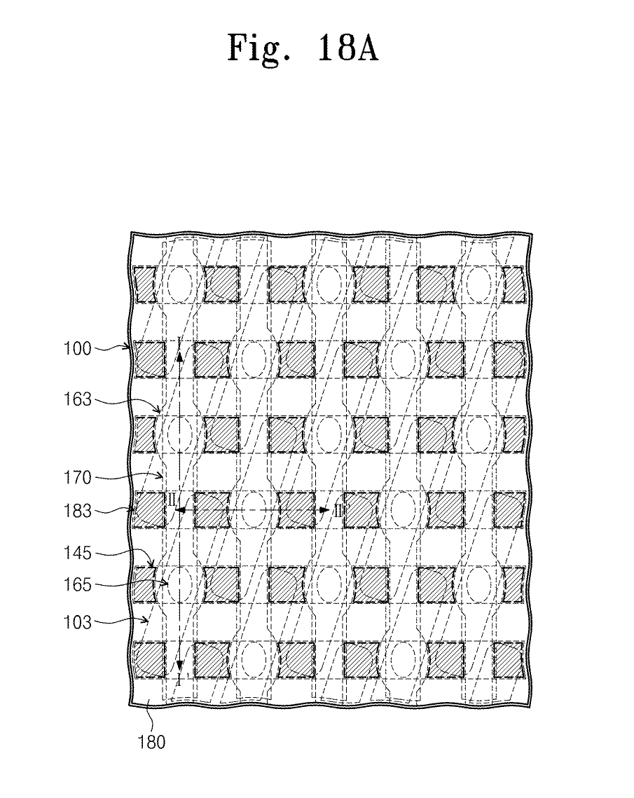

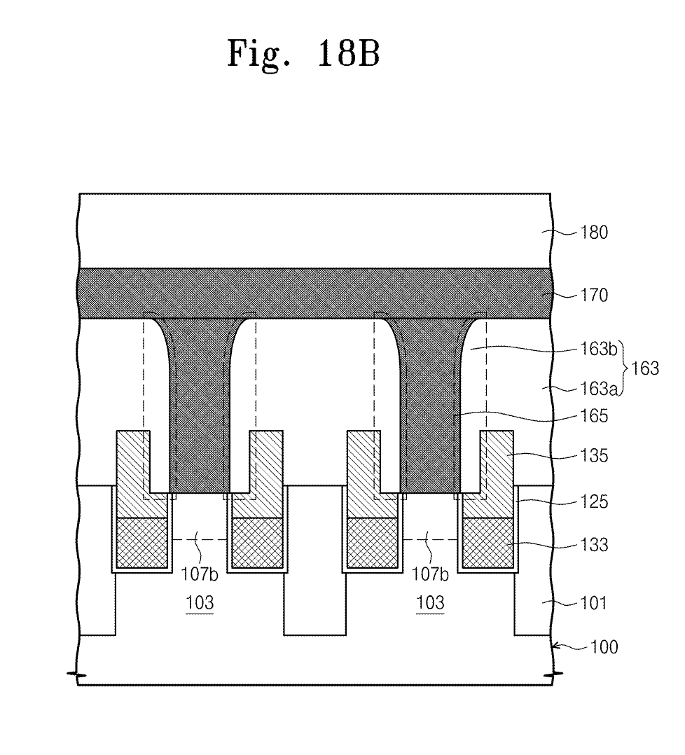

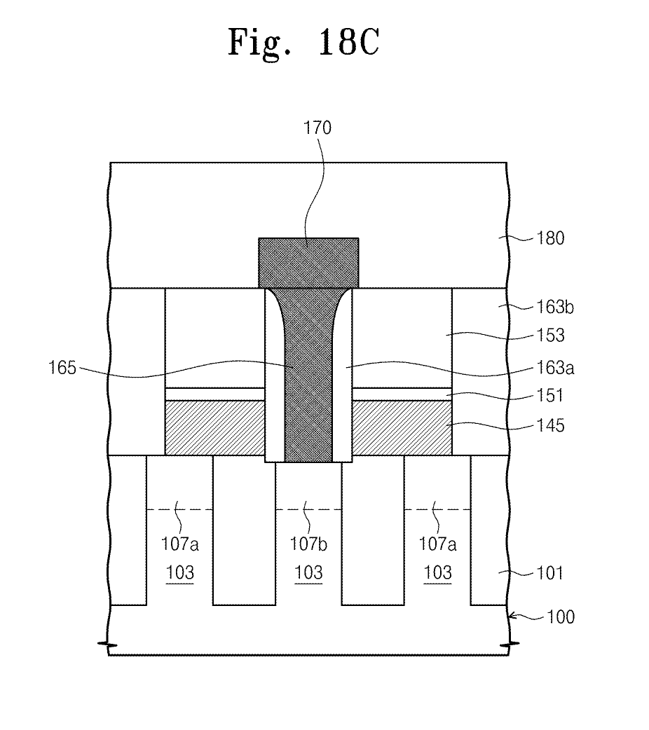

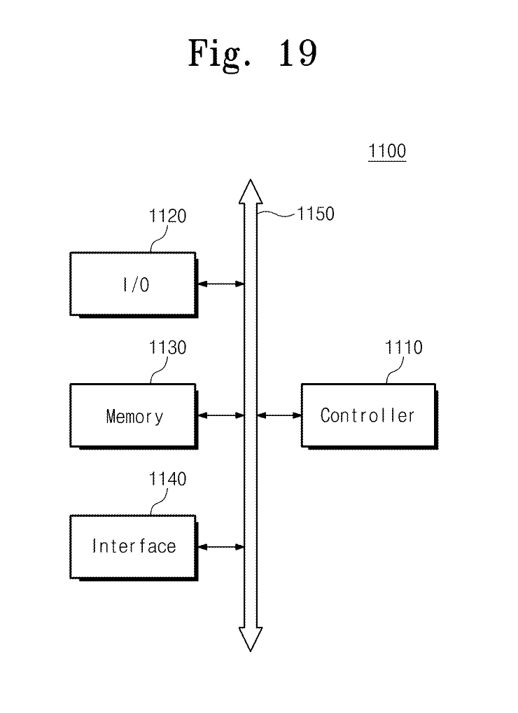

FIG. 19 illustrates an example of a memory system including a semiconductor device in accordance with the inventive concept.

This example of an electronic system 1100 includes a controller 1110, an input/output device 1120, a memory device 1130 comprising a semiconductor memory device according to the inventive concept, an interface 1140 and a bus 1150. The controller 1110, the input/output device 1120, the memory device 1130 and/or the interface 1140 are connected to each other through the bus 1150. The bus 1150 provides a path along which data is transferred.

The controller 1110 may include at least one of a micro processor, a digital signal processor, a microcontroller and a logic device. The input/output device 1120 may include a keypad, a keyboard and a display. The memory device 330 may store data and/or instructions. The interface 1140 allows data to be transmitted to or received from a communications network. The interface 1140 may be a wired (line) type or wireless type. For example, the interface 1140 may include an antenna or a wired/wireless transceiver. Although not illustrated in the drawing, the electronic system 1100 may also include a high speed SRAM device.

Such an electronic system 1100 may be employed by a personal digital assistant (PDA), a portable computer, a web tablet, a mobile phone, a wireless phone, a digital music player, a memory card or any other type of electronic device which can transmit and/or receive data in a wireless environment.

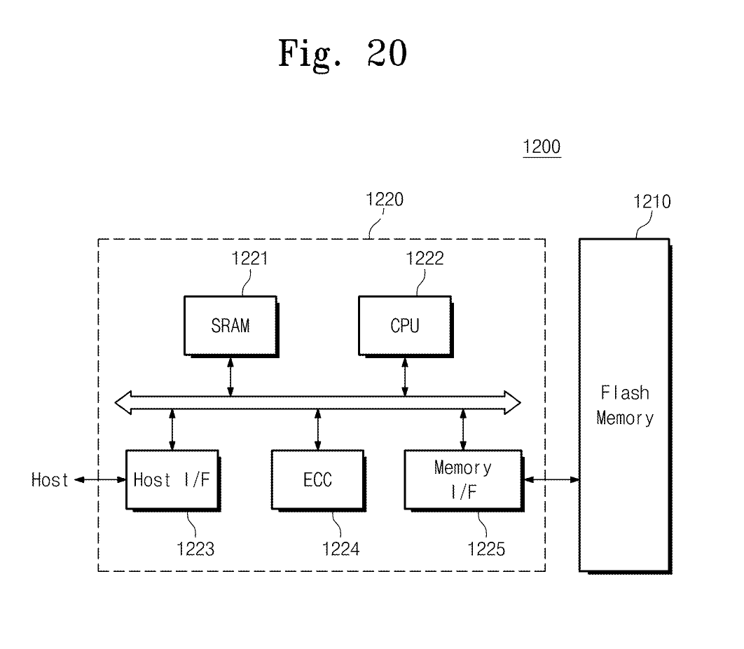

FIG. 20 illustrates an example of a memory card including a semiconductor device in accordance with the inventive concept.

Referring to FIG. 20, this example of a memory card includes a memory device 1210 comprising a semiconductor device according to the inventive concept. The memory device 1210 may also include different types of semiconductor devices (e.g., a nonvolatile memory device and/or a SRAM device). The memory card 1200 also includes a memory controller 1220 controlling a data exchange between a host and the memory device 1210.

The memory controller 1220 of this example includes a central processing unit 1222 controlling the entore operation of the memory card 1200. As shown in the figure, the memory controller 1220 may also include a SRAM 1221 used as an operation memory of the central processing unit 1222. In addition, the memory controller 1220 may further include a host interface 1223 and a memory interface 1225. The host interface 1223 may contain the data exchange protocol between the memory card 1200 and the host. The memory interface 1225 connects the memory controller 1220 and the memory device 1210. The memory controller 1220 may also include an error correction code 1224. In this case, the error correction code 1224 detects and corrects an error read out from the memory device 1210. Although not illustrated in the drawing, the memory card 1200 may also include a ROM device storing code for an interface with the host. Such a memory card 1200 may be used as a portable data storage card. The memory card 1200 may also be embodied as a solid state drive (SSD) which are increasingly being substituted for hard disks.

A semiconductor device according to the inventive concept may be packaged in various ways. For example, a semiconductor device according to the inventive concept can be assembled as part of a PoP (package on package), ball grid array (BGA) package, chip scale package (CSP), plastic leaded chip carrier (PLCC), plastic dual in-line package (PDIP), die in waffle pack, die in wafer form, chip on board (COB) package, ceramic dual in-line package (CERDIP), plastic metric quad flat pack (MQFP), thin quad flat pack (TQFP), small outline IC (SOIC) package, shrink small outline package (SSOP), thin small outline package (TSOP), thin quad flatpack (TQFP), system in package (SIP), multi-chip package (MCP), wafer-level fabricated package (WFP), or wafer-level processed stack package (WSP).

Such a package comprising a semiconductor device in accordance with the inventive concept may also include a controller controlling the semiconductor device and/or a logic device.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A semiconductor memory device comprising:
a substrate, and a device isolation pattern disposed in the substrate and defining an active region, the active region having first and second regions of impurities of different conductivity types;
a buried gate electrode extending longitudinally in one direction and across the active region, wherein the first and second impurity regions are disposed along opposite sides of the buried gate electrode, respectively;
a conductive pad disposed on the substrate and electrically connected to the first impurity region;
a first contact plug disposed on the substrate and electrically connected to the second impurity region; and
a second contact plug disposed on and electrically connected to the pad.

2. The semiconductor memory device of claim 1, wherein the pad directly contacts the first impurity region.

3. The semiconductor memory device of claim 1, wherein part of the pad lies directly over a top surface of the first impurity region, and part of the first contact plug lies directly over the top surface of the first impurity region, such that areas of overlap exist between said part of the pad and the top surface of the first impurity region and between said part of the first contact plug and the top surface of the first impurity region, and
the area of overlap between the pad and the top surface of the first impurity region is greater than the area of overlap between the first contact plug and the top surface of the first impurity region.

4. The semiconductor memory device of claim 1, wherein the pad has a concave side.

5. The semiconductor memory device of claim 1, further comprising a capping pattern disposed on the buried gate electrode, wherein the top surface of the capping pattern is disposed at a level in the device that is substantially even with the level at which the top surface of the pad is located.

6. The semiconductor memory device of claim 5, wherein the capping pattern and the pad directly contact each other.

7. The semiconductor memory device of claim 1, further comprising a first interlayer dielectric film disposed on the substrate, and a second interlayer dielectric film disposed on the first interlayer dielectric film,
wherein the first contact plug extends through the first interlayer dielectric film, and the second contact plug extends through the first interlayer dielectric film and the second interlayer dielectric film.

8. The semiconductor memory device of claim 1, wherein a bottom surface of the second contact plug directly contacts the pad.

9. The semiconductor memory device of claim 1, further comprising:
an interconnection disposed in contact with the first contact plug; and
an information storage element disposed in contact with the second contact plug.

10-14. (canceled)

15. A semiconductor memory device comprising:
a substrate, and a device isolation pattern disposed in the substrate and dividing the substrate into active regions, each of the active region having first regions of impurities of one conductivity type and a second region of impurities of the other conductivity type, wherein the second impurity region is located between the first impurity regions;
buried gate electrodes extending in the substrate parallel to each other longitudinally in a first direction across the active regions and the device isolation pattern therebetween, wherein a pair of the buried gate electrodes crosses each active region and is interposed between the first impurity regions of the active region, and the second impurity region is interposed between the pair of buried gate electrodes;
conductive pads disposed on the substrate and electrically connected to the first impurity regions, respectively;
first contact plugs disposed on the substrate and electrically connected to the second impurity regions, respectively; and
second contact plugs disposed on and electrically connected to the pads, respectively.

16. The semiconductor memory device of claim 15, wherein the pads directly contact the first impurity regions, respectively.

17. The semiconductor memory device of claim 15, wherein part of each pad lies directly over a top surface of a respective one of the first impurity regions, and part of each first contact plug lies directly over the top surface of the first impurity region, such that areas of overlap exist between said part of the pad and the top surface of the first impurity region and between said part of the first contact plug and the top surface of the first impurity region, and
the area of overlap between the pad and the top surface of the first impurity region is greater than the area of overlap between the first contact plug and the top surface of the first impurity region.

18. The semiconductor memory device of claim 15, further comprising dielectric patterns extending across the active regions and the device isolation pattern therebetween, the dielectric patterns extending parallel to each other longitudinally in a second direction that crosses the first direction, each of the dielectric patterns having linear portions, and ring-shaped portions connected by the linear portions, and each of the ring-shaped portions surrounding a respective one of the first contact plugs.

19. The semiconductor memory device of claim 18, wherein each of the pads has a concave surface facing and complementary to the outer surface of a respective one of the ring-shaped portions.

20. The semiconductor memory device of claim 18, wherein the first contact plugs are arrayed in a plurality of columns, further comprising conductive lines each disposed on and electrically connecting the first contact plugs of a respective column.
